(19) United States
(12) Patent Application Publication
(10) Pub. No.: US 2025/0014961 A1
(43) Pub. Date: Jan. 9, 2025

(54) GAP-FILL DIELECTRICS FOR DIE STRUCTURES AND METHODS OF FORMING THE SAME

(71) Applicant: Taiwan Semiconductor Manufacturing Co., Ltd., Hsinchu (TW)

(72) Inventors: Chih-Hong Wang, Taipei City (TW); Chen-Shien Chen, Zhubei City (TW); Ting Hao Kuo, Hsinchu (TW); Yu-Chia Lai, Zhunan Township (TW)

(21) Appl. No.: 18/404,243

(22) Filed: Jan. 4, 2024

Related U.S. Application Data
(60) Provisional application No. 63/610,148, filed on Dec. 14, 2023.
(60) Provisional application No. 63/512,526, filed on Jul. 7, 2023.

(51) Int. Cl. H01L 23/31; H01L 21/56; H01L 23/00; H01L 23/48; H01L 25/065

(52) U.S. Cl. CPC H01L 23/3185; H01L 21/568; H01L 23/481; H01L 24/08; H01L 24/20; H01L 24/80; H01L 25/0652; H01L 2224/08145; H01L 2224/21; H01L 2224/80895; H01L 2224/80896

(57) ABSTRACT

Gap-fill dielectrics for die structures and methods of forming the same are provided. In an embodiment, a device includes: an outer gap-fill dielectric having a first coefficient of thermal expansion; a first integrated circuit die in the outer gap-fill dielectric; a second integrated circuit die in the outer gap-fill dielectric; an inner gap-fill dielectric between the first integrated circuit die and the second integrated circuit die, the inner gap-fill dielectric having a second coefficient of thermal expansion, the second coefficient of thermal expansion being greater than the first coefficient of thermal expansion; and a third integrated circuit die over the inner gap-fill dielectric, the third integrated circuit die bonded to the first integrated circuit die and to the second integrated circuit die.

### PRIORITY CLAIM AND CROSS-REFERENCE

This application claims the benefit of U.S. Provisional Application No. 63/610,148, filed on Dec. 14, 2023, and U.S. Provisional Application No. 63/512,526, filed on Jul. 7, 2023, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die.

FIGS. 2-12 are cross-sectional views of intermediate stages in the manufacturing of a die structure, in accordance with some embodiments.

FIGS. 13A-13C are cross-sectional views of die structures, in accordance with various embodiments.

FIGS. 14-15 are cross-sectional views of intermediate stages in the manufacturing of a die structure, in accordance with some other embodiments.

FIGS. 16-19 are cross-sectional views of intermediate stages in the manufacturing of a die structure, in accordance with some other embodiments.

FIGS. 20-26 are cross-sectional views of intermediate stages in the manufacturing of a die structure, in accordance with some other embodiments.

FIGS. 27A-27D are cross-sectional views of die structures, in accordance with various embodiments.

FIG. 28 is a cross-sectional view of a die structure, in accordance with some other embodiments.

FIGS. 29A-29C are top-down views of die structures, in accordance with various embodiments.

FIG. 30 is a cross-sectional view of a die structure, in accordance with some other embodiments.

FIG. 31 is a cross-sectional view of a die structure, in accordance with some other embodiments.

FIG. 32 is a cross-sectional view of a die structure, in accordance with some other embodiments.

FIGS. 33-36 are cross-sectional views of intermediate stages in the manufacturing of a die structure, in accordance with some other embodiments.

FIG. 37 is a cross-sectional view of an integrated circuit package, in accordance with some embodiments.

FIG. 38 is a cross-sectional view of an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a die structure includes a layer of integrated circuit dies and multiple gap-fill dielectrics. Specifically, the integrated circuit dies are in an outer gap-fill dielectric, and an inner gap-fill dielectric is between the integrated circuit dies. The inner gap-fill dielectric has a higher CTE than the outer gap-fill dielectric. The CTE of the inner gap-fill dielectric may be matched to the CTE of the integrated circuit dies, which can reduce a CTE mismatch in the die structure. The risk of warping the die structure and/or inducing undesirable stresses on the integrated circuit dies may be reduced, which may increase the reliability and/or yield of the die structure.

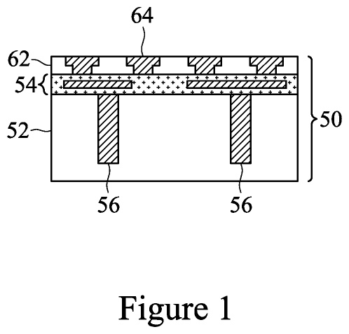

FIG. 1 is a cross-sectional view of an integrated circuit die 50. The integrated circuit die 50 will be bonded to other dies in subsequent processing to form a die structure. The integrated circuit die 50 may be a logic die (e.g., central processing unit (CPU), graphics processing unit (GPU), system-on-a-chip (SoC) die, application processor (AP), microcontroller, etc.), a memory die (e.g., dynamic random access memory (DRAM) die, static random access memory (SRAM) die, etc.), a bridge die (e.g., a local silicon interconnect (LSI) die), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated to form a plurality of integrated circuit dies. The integrated circuit die 50 may be processed according to applicable manufacturing processes to form integrated circuits. For example, the integrated circuit die 50 includes a semiconductor substrate 52, which may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward in FIG. 1) and an inactive surface (e.g., the surface facing downward in FIG. 1). Devices (not separately illustrated) may be formed in and/or on the active surface of the semiconductor substrate 52. The devices may be active devices (e.g., transistors, diodes, etc.) and/or passive devices (e.g., capacitors, inductors, resistors, etc.). The inactive surface may be free from devices.

An interconnect structure 54 is disposed over the active surface of the semiconductor substrate 52, and is used to electrically connect the devices of the semiconductor substrate 52 to form an integrated circuit. The interconnect structure 54 may include one or more dielectric layer(s) and respective metallization layer(s) in the dielectric layer(s). The dielectric layer(s) may be, e.g., low-k dielectric layer(s). The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The metallization layer(s) of the interconnect structure 54 may be formed by a damascene process, such as a single damascene process, a dual damascene process, or the like.

Optionally, conductive vias 56 extend into the interconnect structure 54 and/or the semiconductor substrate 52. The conductive vias 56 are electrically coupled to the metallization layer(s) of the interconnect structure 54. As an example to form the conductive vias 56, recesses can be formed in the interconnect structure 54 and/or the semiconductor substrate 52 by, for example, etching, milling, laser techniques, a combination thereof, or the like. A thin barrier layer may be conformally deposited in the recesses, such as by chemical vapor deposition (CVD), atomic layer deposition (ALD), physical vapor deposition (PVD), thermal oxidation, a combination thereof, or the like. The barrier layer may be formed of an oxide, a nitride, combinations thereof, or the like. A conductive material may be formed over the barrier layer and in the recesses. The conductive material may be formed by an electro-chemical plating process, CVD, ALD, PVD, a combination thereof, or the like. Examples of conductive materials include copper, tungsten, aluminum, silver, gold, a combination thereof, or the like. Excess conductive material and barrier layer is removed from a surface of the interconnect structure 54 or the semiconductor substrate 52 by, for example, a chemical-mechanical polish (CMP). The remaining portions of the barrier layer and conductive material in the recesses form the conductive vias 56. After their initial formation, the conductive vias 56 may be buried in the semiconductor substrate 52. The semiconductor substrate 52 may be thinned in subsequent processing to expose the conductive vias 56 at the inactive surface of the semiconductor substrate 52. After the exposure process, the conductive vias 56 are through-substrate vias (TSVs), such as through-silicon vias, that extend through the semiconductor substrate 52.

A dielectric layer 62 is over the interconnect structure 54, at the front-side of the integrated circuit die 50. The dielectric layer 62 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a polymer such as polybenzoxazole (PBO), polyimide, a benzocyclobutene (BCB) based polymer, or the like; a combination thereof; or the like. The dielectric layer 62 may be formed, for example, by CVD, spin coating, lamination, or the like. Optionally, one or more passivation layer(s) (not separately illustrated) are disposed between the dielectric layer 62 and the interconnect structure 54.

Die connectors 64 extend through the dielectric layer 62. The die connectors 64 may include conductive pillars, pads, or the like, to which external connections can be made. In some embodiments, the die connectors 64 include bond pads at the front-side of the integrated circuit die 50, and include bond pad vias that connect the bond pads to an upper metallization layer of the interconnect structure 54. In such embodiments, the die connectors 64 (including the bond pads and the bond pad vias) may be formed by a damascene process, such as a single damascene process, a dual damascene process, or the like. The die connectors 64 may be formed of a suitable conductive material, such as copper, tungsten, aluminum, silver, gold, a combination thereof, or the like, which can be formed by, for example, plating or the like.

Optionally, chip probe (CP) testing may be performed on the integrated circuit die 50. For example, a chip probe may be attached to test pads (not separately illustrated). Chip probe testing may be performed on the integrated circuit die 50 to ascertain whether the integrated circuit die 50 is a known good die (KGD). Thus, only integrated circuit dies 50, which are KGDs, undergo subsequent processing are packaged, and dies which fail the chip probe testing are not packaged.

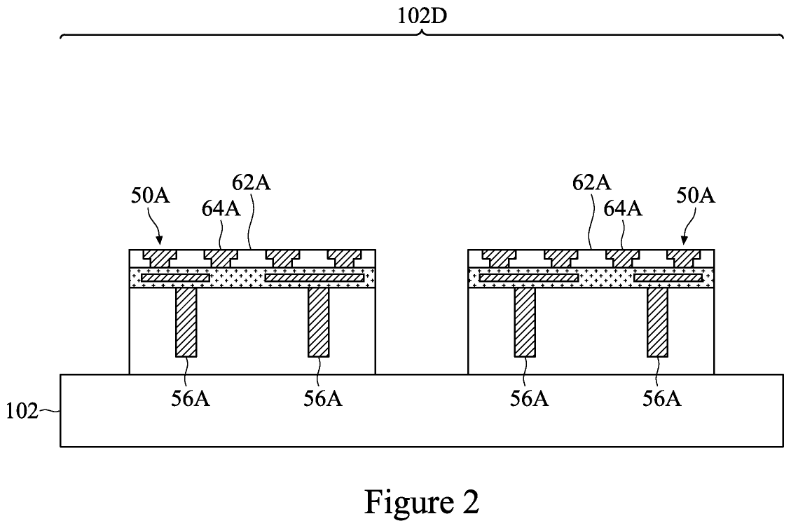

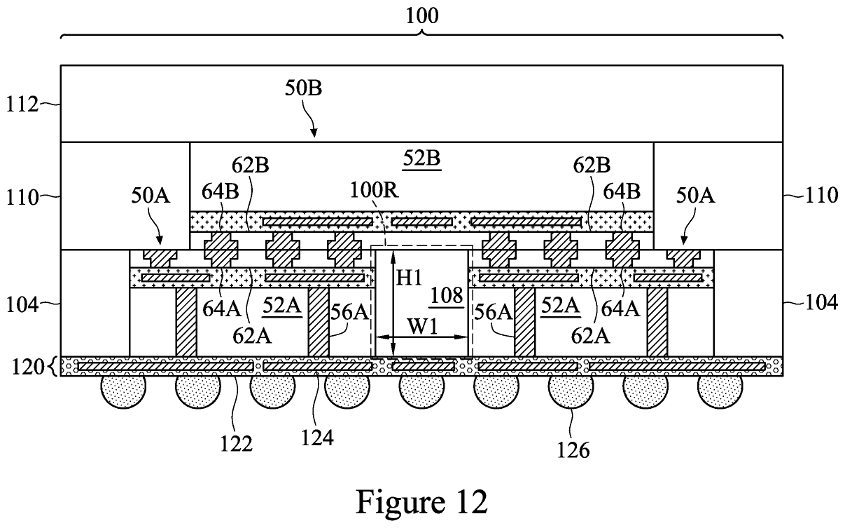

FIGS. 2-12 are cross-sectional views of intermediate stages in the manufacturing of a die structure 100 (see FIG. 12), in accordance with some embodiments. The die structure 100 is a stack of integrated circuit dies 50 (including first integrated circuit dies 50A and a second integrated circuit die 50B). The die structure 100 is formed by bonding the integrated circuit dies 50 together in a device region 102D. The device region 102D will be singulated to form the die structure 100. Processing of one device region 102D is illustrated, but it should be appreciated that any number of device regions 102D can be simultaneously processed to form any number of the die structures 100.

A die structure 100 (see FIG. 12) is a component that may be subsequently packaged to form an integrated circuit package. The integrated circuit dies of the die structure 100 may be heterogeneous dies. Packaging the die structure 100 in lieu of packaging the dies individually may allow heterogeneous dies to be integrated with a small footprint. The die structure 100 may be a system-on-integrated-chips (SoIC) device, although other types of devices may be formed.

In FIG. 2, a carrier substrate 102 is provided. The carrier substrate 102 may be a glass carrier substrate, a ceramic carrier substrate, or the like. The carrier substrate 102 may be a wafer, such that multiple packages can be formed on the carrier substrate 102 simultaneously.

First integrated circuit dies 50A are attached to a carrier substrate 102 in a face-up manner, such that the back-sides of first integrated circuit dies 50A are attached to the carrier substrate 102. In the illustrated embodiment, two first integrated circuit dies 50A are attached in the device region 102D, although any desired quantity of first integrated circuit dies 50A may be attached in the device region 102D. The first integrated circuit dies 50A each have a similar structure to that described for FIG. 1. In some embodiments, the first integrated circuit dies 50A include logic dies and/or memory dies. Additionally, some of the first integrated circuit dies 50A may be dummy dies that are used to provide structural support.

The first integrated circuit dies 50A may be attached to the carrier substrate 102 by placing the first integrated circuit dies 50A on the carrier substrate 102, and then bonding the first integrated circuit dies 50A to the carrier substrate 102. The first integrated circuit dies 50A may be placed by, e.g., a pick-and-place process. The bonding process may include fusion bonding, dielectric bonding, or the like. As an example of the bonding process, the first integrated circuit dies 50A may be boned to the carrier substrate 102 with one or more bonding layer(s) (not separately illustrated). The bonding layer(s) are on back-sides of the first integrated circuit dies 50A and/or on a surface of the carrier substrate 102. In some embodiments, the bonding layer(s) include an oxide layer such as a layer of silicon oxide. In some embodiments, the bonding layer(s) include an adhesive, such as a suitable epoxy, a die attach film (DAF), or the like. The bonding layer(s) may be applied to back-sides of the first integrated circuit dies 50A, may be applied over the surface of the carrier substrate 102, and/or the like. For example, the bonding layer(s) may be applied to the back-sides of the first integrated circuit dies 50A before singulating to separate the first integrated circuit dies 50A.

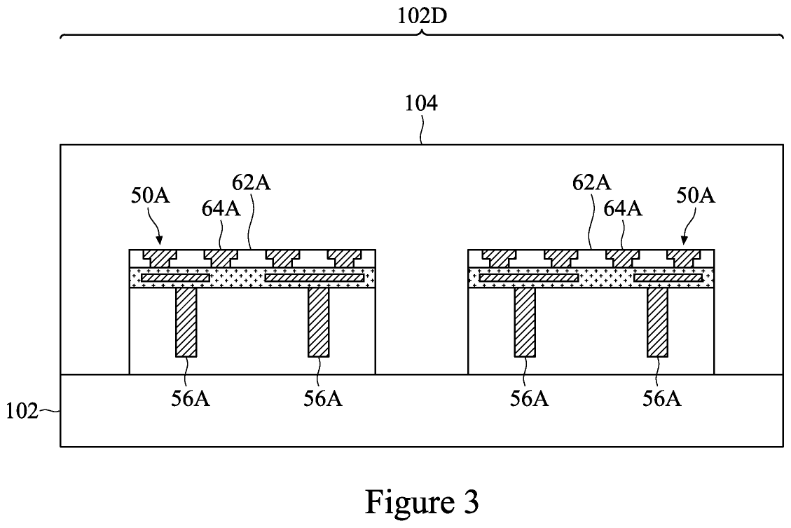

In FIG. 3, an outer gap-fill dielectric 104 is formed over and around the first integrated circuit dies 50A. The outer gap-fill dielectric 104 is a dielectric feature that surrounds and protects the first integrated circuit dies 50A. The outer gap-fill dielectric 104 may be formed of one or more dielectric materials. Acceptable gap-fill dielectric materials include oxides such as silicon oxide, phosphosilicate glass (PSG), borosilicate glass (BSG), boron-doped phosphosilicate glass (BPSG), a tetraethyl orthosilicate (TEOS) based oxide, or the like; nitrides such as silicon nitride or the like; combinations thereof; or the like, which may be formed by a suitable deposition process such as chemical vapor deposition (CVD), atomic layer deposition (ALD), or the like. Other acceptable dielectric materials, such as resins, molding compounds, or the like may be utilized. In some embodiments, the outer gap-fill dielectric 104 is multi-layered. Initially, the outer gap-fill dielectric 104 may be formed on the first integrated circuit dies 50A, such that the outer gap-fill dielectric 104 buries or covers the first integrated circuit dies 50A. Accordingly, the top surface of the outer gap-fill dielectric 104 may initially be above the front-sides of the first integrated circuit dies 50A.

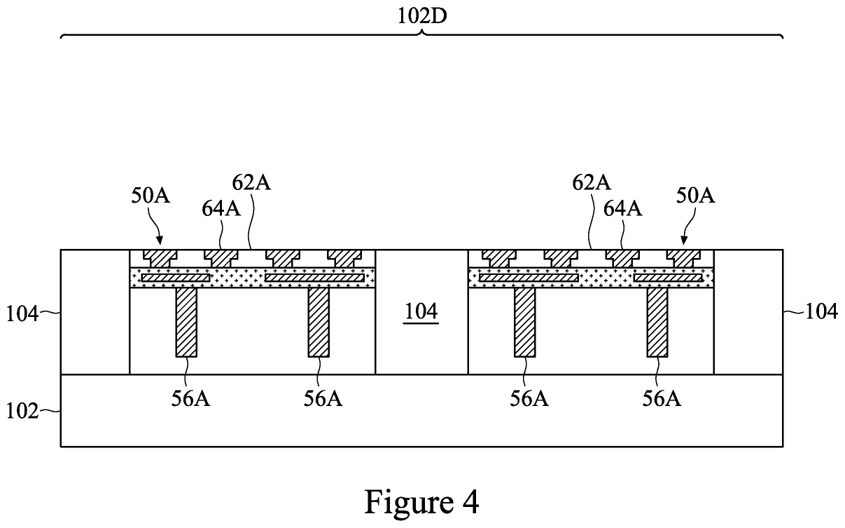

In FIG. 4, a removal process may optionally be performed to level the upper surface of the outer gap-fill dielectric 104 with the front-sides of the first integrated circuit dies 50A (e.g., the dielectric layers 62A of the first integrated circuit dies 50A). The remaining portions of the outer gap-fill dielectric 104 above the first integrated circuit dies 50A are removed. In some embodiments, a planarization process such as a chemical mechanical polish (CMP), an etch-back process, combinations thereof, or the like is utilized. The front-sides of the first integrated circuit dies 50A may thus be exposed through the outer gap-fill dielectric 104.

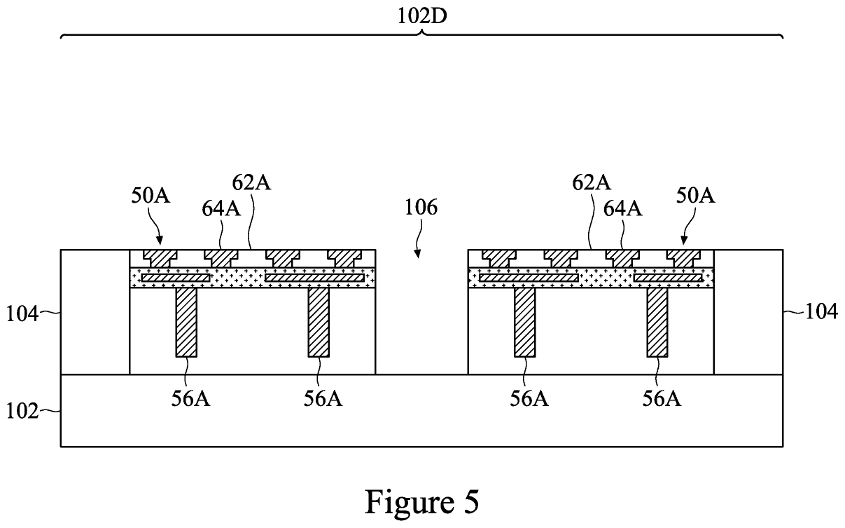

In FIG. 5, the outer gap-fill dielectric 104 is patterned to remove portions of the outer gap-fill dielectric 104 between the first integrated circuit dies 50A, thus forming a recess 106 between the first integrated circuit dies 50A. Initially, the outer gap-fill dielectric 104 may be in the outer portion and the inner portion of the device region 102D. The patterning removes the outer gap-fill dielectric 104 from the inner portion of the device region 102D, such that the outer gap-fill dielectric 104 remains in the outer portion of the device region 102D. The outer gap-fill dielectric 104 may be patterned using acceptable photolithography and etching techniques.

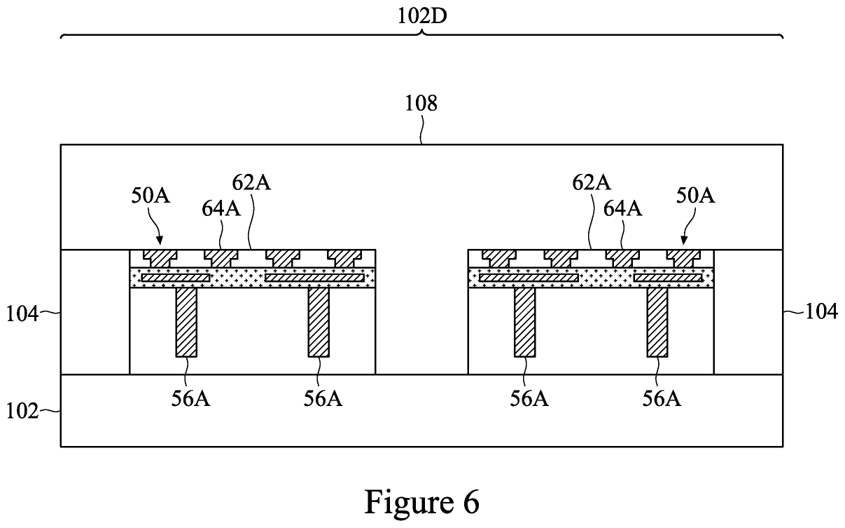

In FIG. 6, an inner gap-fill dielectric 108 is formed in the recess 106 and over the outer gap-fill dielectric 104 and the first integrated circuit dies 50A. The inner gap-fill dielectric 108 is a dielectric feature that fills the gaps between the first integrated circuit dies 50A. In this embodiment, the inner gap-fill dielectric 108 physically contacts the inner sidewalls of the first integrated circuit dies 50A. The inner gap-fill dielectric 108 may be formed of one or more dielectric materials. Acceptable gap-fill dielectric materials include oxides such as silicon oxide, phosphosilicate glass (PSG), borosilicate glass (BSG), boron-doped phosphosilicate glass (BPSG), a tetraethyl orthosilicate (TEOS) based oxide, or the like; nitrides such as silicon nitride or the like; combinations thereof; or the like, which may be formed by a suitable deposition process such as chemical vapor deposition (CVD), atomic layer deposition (ALD), or the like. Other acceptable dielectric materials, such as resins, molding compounds, or the like may be utilized. In some embodiments, the inner gap-fill dielectric 108 is multi-layered. As subsequently described in greater detail, the inner gap-fill dielectric 108 is different than the outer gap-fill dielectric 104. Initially, the inner gap-fill dielectric 108 may be formed on the outer gap-fill dielectric 104 and the first integrated circuit dies 50A, such that the inner gap-fill dielectric 108 buries or covers the first integrated circuit dies 50A. Accordingly, the top surface of the inner gap-fill dielectric 108 may initially be above the front-sides of the first integrated circuit dies 50A.

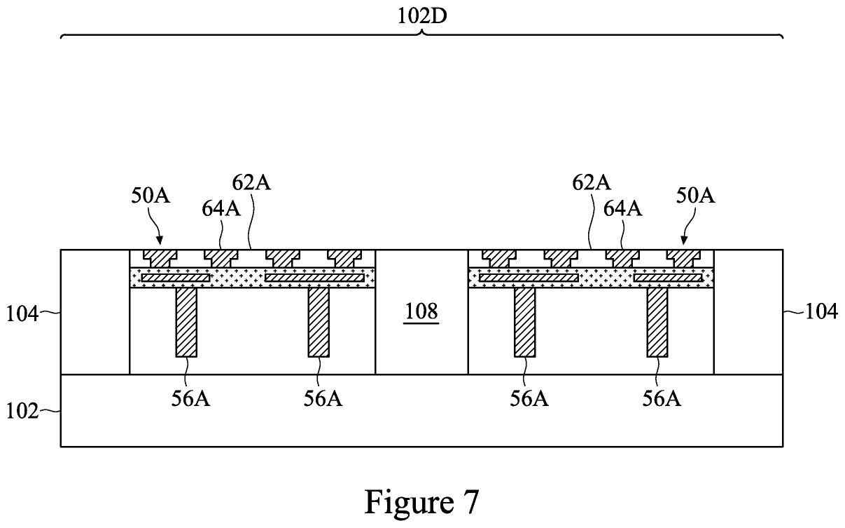

In FIG. 7, a removal process is performed to level the upper surface of the inner gap-fill dielectric 108 with the front-sides of the first integrated circuit dies 50A (e.g., the dielectric layers 62A of the first integrated circuit dies 50A) and the upper surface of the outer gap-fill dielectric 104. The remaining portions of the inner gap-fill dielectric 108 above the first integrated circuit dies 50A are removed. In some embodiments, a planarization process such as a chemical mechanical polish (CMP), an etch-back process, combinations thereof, or the like is utilized. The front-sides of the first integrated circuit dies 50A may thus be exposed through the inner gap-fill dielectric 108 and the outer gap-fill dielectric 104. Initially, the inner gap-fill dielectric 108 may be in the outer portion and the inner portion of the device region 102D. The removal process removes the inner gap-fill dielectric 108 from the outer portion of the device region 102D, such that the inner gap-fill dielectric 108 remains in the inner portion of the device region 102D.

In this embodiment, the first integrated circuit dies 50A are attached to a carrier substrate 102 before each of the outer gap-fill dielectric 104 and the inner gap-fill dielectric 108 are formed. Further, the inner gap-fill dielectric 108 is formed after the outer gap-fill dielectric 104. In other embodiments (subsequently described), the inner gap-fill dielectric 108 is formed before the outer gap-fill dielectric 104. In yet other embodiments (subsequently described), the first integrated circuit dies 50A are attached to a carrier substrate 102 after each of the outer gap-fill dielectric 104 and the inner gap-fill dielectric 108 are formed.

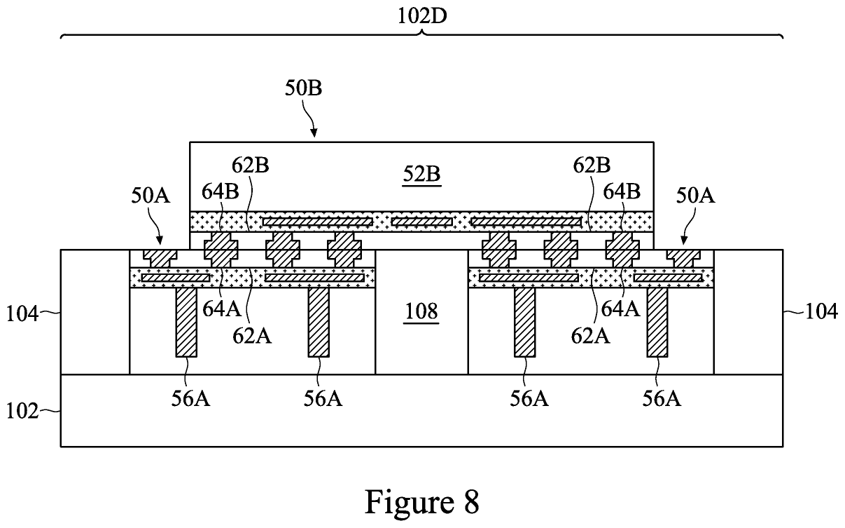

In FIG. 8, a second integrated circuit die 50B is attached to the first integrated circuit dies 50A, such that the front-side of the second integrated circuit die 50B faces the front-sides of the first integrated circuit dies 50A. In the illustrated embodiment, one second integrated circuit die 50B is attached in the device region 102D, although any desired quantity of second integrated circuit dies 50B may be attached in the device region 102D. The function of the second integrated circuit die 50B may (or may not) be different than the function(s) of the first integrated circuit dies 50A. The first integrated circuit dies 50A and the second integrated circuit die 50B may be formed in processes of a same technology node, or may be formed in processes of different technology nodes. For example, the first integrated circuit dies 50A may be formed of a more advanced technology node than the second integrated circuit die 50B. The second integrated circuit die 50B may be wider than each of the first integrated circuit dies 50A.

The second integrated circuit die 50B is disposed above the inner gap-fill dielectric 108. In some embodiments, the second integrated circuit die 50B is a cross-die communication module, such as a bridge die. The bridge die is attached to the first integrated circuit dies 50A such that the bridge die overlaps more than one of the first integrated circuit dies 50A and the inner gap-fill dielectric 108 between the first integrated circuit dies 50A. The bridge die may (or may not) be substantially free of any active or passive devices. As such, the semiconductor substrate of the bridge die may be undoped. The bridge die is electrically coupled to the first integrated circuit dies 50A, and may be utilized to interconnect the devices of the first integrated circuit dies 50A.

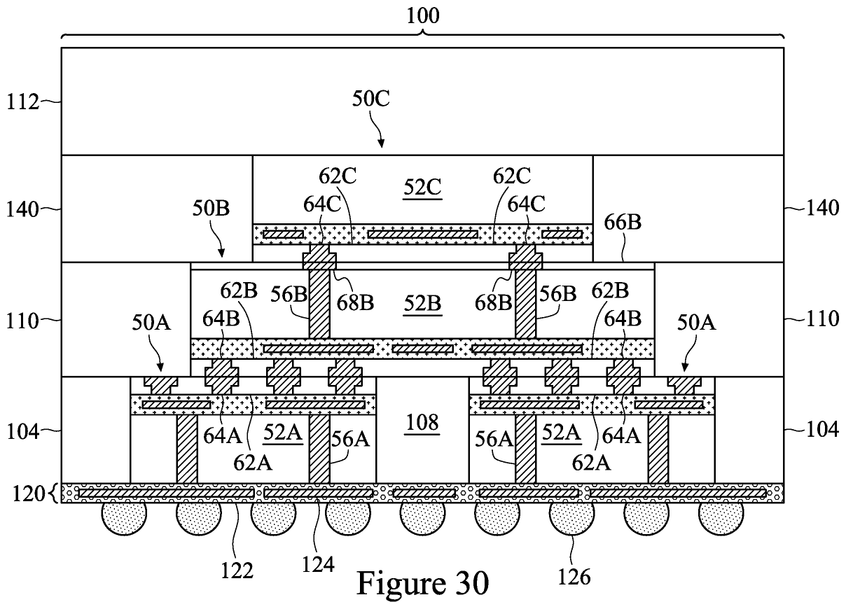

The second integrated circuit die 50B has a similar structure to that described for FIG. 1, except the second integrated circuit die 50B do not include the conductive vias 56. The die structure 100 may include two layers of integrated circuit dies 50, and the conductive vias 56 are excluded from the second integrated circuit die 50B because the second integrated circuit die 50B is the upper layer of integrated circuit dies 50 in the die structure 100. In other embodiments (subsequently described for FIG. 30), the die structure 100 includes more than two layers of integrated circuit dies 50, such as three layers of integrated circuit dies 50, and the conductive vias 56 may be formed in other layers of integrated circuit dies 50 besides the upper layer of integrated circuit dies 50.

The second integrated circuit die 50B is directly bonded to the first integrated circuit dies 50A. In this embodiment, the second integrated circuit die 50B and the first integrated circuit dies 50A are directly bonded in a face-to-face manner, such that the front-side of the second integrated circuit die 50B is bonded to the front-sides of the first integrated circuit dies 50A. The second integrated circuit die 50B may be bonded to the first integrated circuit dies 50A by hybrid bonding. In hybrid bonding, the dielectric layer 62B of the second integrated circuit die 50B is bonded to the dielectric layers 62A of the first integrated circuit dies 50A through dielectric-to-dielectric bonding, without using any adhesive material (e.g., die attach film), and the die connectors 64B of the second integrated circuit die 50B are bonded to the die connectors 64A of the first integrated circuit dies 50A through metal-to-metal bonding, without using any reflowable material (e.g., solder). The bonding may include a pre-bonding and an annealing. During the pre-bonding, a small pressing force is applied to press the second integrated circuit die 50B against the first integrated circuit dies 50A. The pre-bonding is performed at a low temperature, such as room temperature, and after the pre-bonding, the dielectric layer 62B is bonded to the dielectric layers 62A. The bonding strength is then improved in a subsequent annealing step, in which the dielectric layer 62A, 62B are annealed at a high temperature, such as a temperature in the range of 100° C. to 450° C. The annealing forms bonds, such as fusions bonds, that bond the dielectric layer 62B to the dielectric layers 62A. For example, the bonds can be covalent bonds between the material of the dielectric layer 62B and the material of the dielectric layers 62A. The die connectors 64B are connected to the die connectors 64A with a one-to-one correspondence. The die connectors 64B may be in physical contact with the die connectors 64A after the pre-bonding, or the die connectors 64A, 64B may expand to be brought into physical contact during the annealing. Further, during the annealing, the material of the die connectors 64A, 64B (e.g., copper) intermingles, so that metal-to-metal bonds are also formed. Hence, the resulting bonds between the second integrated circuit die 50B and the first integrated circuit dies 50A include both dielectric-to-dielectric bonds and metal-to-metal bonds.

The coefficient of thermal expansion (CTE) of the integrated circuit dies 50 may be largely determined by the CTE of the semiconductor substrates 52, which are formed of a semiconductor material. The semiconductor material of the integrated circuit dies 50 has a large CTE as compared to that of the outer gap-fill dielectric 104, such that there may be a CTE mismatch between the integrated circuit dies 50 and the outer gap-fill dielectric 104. An unmitigated CTE mismatch may warp the die structure 100 and/or induce undesirable stresses on some of the integrated circuit dies 50 (e.g., the second integrated circuit die 50B, particularly when it is a bridge die). The inner gap-fill dielectric 108 is different than the outer gap-fill dielectric 104, and may mitigate the effects of a CTE mismatch between the integrated circuit dies 50 and the outer gap-fill dielectric 104. The inner gap-fill dielectric 108 may have a greater CTE than the outer gap-fill dielectric 104 and/or the inner gap-fill dielectric 108 may have a greater compressive strength than the outer gap-fill dielectric 104.

In some embodiments, the CTE of the inner gap-fill dielectric 108 is greater than the CTE of the outer gap-fill dielectric 104. Replacing some of the outer gap-fill dielectric 104 (having a low CTE) with the inner gap-fill dielectric 108 (having a high CTE) can reduce a CTE mismatch in the die structure 100. The CTE of the inner gap-fill dielectric 108 may be matched to the CTE of the integrated circuit dies 50, such that the CTE of the inner gap-fill dielectric 108 is closer to the CTE of the integrated circuit dies 50 than to the CTE of the outer gap-fill dielectric 104. For example, the difference between the CTE of the inner gap-fill dielectric 108 and the CTE of the integrated circuit dies 50 may be less than 10% the CTE of the integrated circuit dies 50. In some embodiments, the CTE of the gap-fill dielectric 104 is in the range of 0.55×10⁻⁶/K to 0.75×10⁻⁶/K (such as about 0.6×10⁻⁶/K), the CTE of the inner gap-fill dielectric 108 is in the range of 2.5×10⁻⁶/K to 4.2×10⁻⁶/K (such as about 3×10⁻⁶/K), and the CTE of the integrated circuit dies 50 is in the range of 2.5×10⁻⁶/K to 3.5×10⁻⁶/K (such as about 2.8×10⁻⁶/K).

In some embodiments, the compressive strength of the inner gap-fill dielectric 108 is greater than the compressive strength of the outer gap-fill dielectric 104. The compressive strength of the inner gap-fill dielectric 108 being large allows it to resist warpage of the die structure 100 and/or counter undesirable stresses on the integrated circuit dies 50. Additionally, the compressive strength of the inner gap-fill dielectric 108 being large may help avoid deformation during the bonding of the second integrated circuit die 50B to the first integrated circuit dies 50A. In some embodiments, the compressive strength of the gap-fill dielectric 104 is up to 300 MPa while the compressive strength of the inner gap-fill dielectric 108 is up to 500 MPa.

The CTE and/or compressive strength of the inner gap-fill dielectric 108 is determined by the material composition of the inner gap-fill dielectric 108. As subsequently described in greater detail, the material composition of the inner gap-fill dielectric 108 is chosen so that the inner gap-fill dielectric 108 has a greater CTE and/or a greater compressive strength than the outer gap-fill dielectric 104. Specifically, the inner gap-fill dielectric 108 is formed of a material that is doped to have a CTE that is matched to the CTE of the integrated circuit dies 50.

In some embodiments, the inner gap-fill dielectric 108 is formed of a silicon-based dielectric material that is doped with a non-silicon impurity. The non-silicon impurity may be nitrogen, phosphorous, boron, fluorine, carbon, or the like. Acceptable impurity-containing silicon-based dielectric materials include silicon oxynitride, phosphosilicate glass (PSG), borosilicate glass (BSG), fluorinated silicon dioxide, carbon-doped silicon dioxide, combinations thereof, or the like. The CTE and/or compressive strength of such an inner gap-fill dielectric 108 may be determined by the concentration of the non-silicon impurity. The inner gap-fill dielectric 108 may be formed of an impurity-rich material. The impurity concentration of the inner gap-fill dielectric 108 may be greater than the impurity concentration of the outer gap-fill dielectric 104, which may allow the CTE of the inner gap-fill dielectric 108 to be greater than the CTE of the outer gap-fill dielectric 104. In some embodiments, the impurity is nitrogen, and the nitrogen concentration of the inner gap-fill dielectric 108 is in the range of 7% to 75% (such as at least about 66%). The nitrogen concentration of the inner gap-fill dielectric 108 being less than 7% may be insufficient to mitigate the effects of a CTE mismatch between the integrated circuit dies 50 and the outer gap-fill dielectric 104. The nitrogen concentration of the inner gap-fill dielectric 108 being greater than 75% may result in the inner gap-fill dielectric 108 being low in quality and/or may cause the CTE of the inner gap-fill dielectric 108 to be mismatched with the CTE of the integrated circuit dies 50.

In some embodiments, the inner gap-fill dielectric 108 is formed of a transition metal oxide. Acceptable transition metal oxides include tantalum pentoxide, hafnium oxide, zirconium oxide, combinations thereof, or the like. The compressive strength of such an inner gap-fill dielectric 108 may be determined by the concentration of the transition metal. The inner gap-fill dielectric 108 may be formed of a transition-metal-rich material. The transition metal concentration of the inner gap-fill dielectric 108 may be high, which may allow the compressive strength of the inner gap-fill dielectric 108 to be large. In some embodiments, the transition metal is tantalum, hafnium, zirconium, or the like, and the transition metal concentration of the inner gap-fill dielectric 108 is in the range of 60% to 90%. The transition metal concentration of the inner gap-fill dielectric 108 may be greater than the transition metal concentration of the outer gap-fill dielectric 104.

The relative permittivity of the outer gap-fill dielectric 104 may be less than the relative permittivity of the inner gap-fill dielectric 108, which may allow the outer gap-fill dielectric 104 to provide good electrical isolation. The outer gap-fill dielectric 104 may be formed of an oxygen-rich material. Specifically, the oxygen concentration of the outer gap-fill dielectric 104 may be greater than the oxygen concentration of the inner gap-fill dielectric 108, which may allow the relative permittivity of the outer gap-fill dielectric 104 to be less than the relative permittivity of the inner gap-fill dielectric 108.

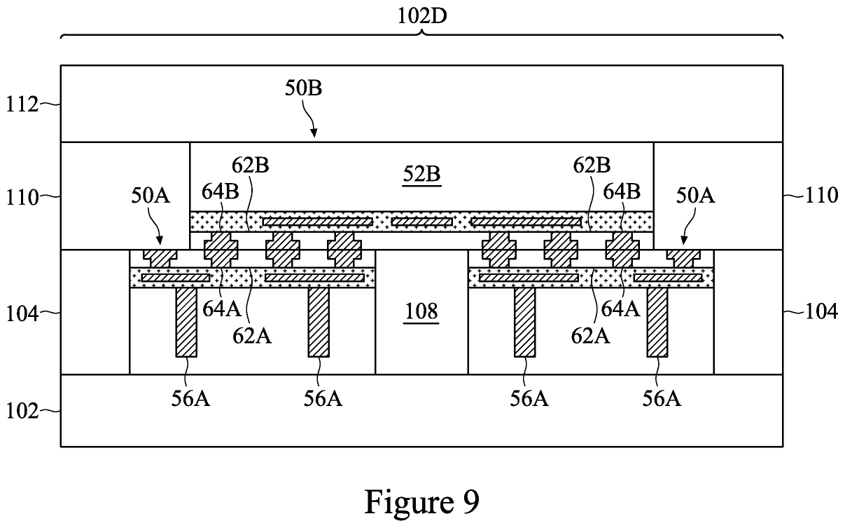

In FIG. 9, a gap-fill dielectric 110 is formed around the second integrated circuit die 50B. The gap-fill dielectric 110 is a dielectric feature that surrounds and protects the second integrated circuit die 50B. The gap-fill dielectric 110 may be formed of one or more dielectric materials. Acceptable gap-fill dielectric materials include oxides such as silicon oxide, phosphosilicate glass (PSG), borosilicate glass (BSG), boron-doped phosphosilicate glass (BPSG), a tetraethyl orthosilicate (TEOS) based oxide, or the like; nitrides such as silicon nitride or the like; combinations thereof; or the like, which may be formed by a suitable deposition process such as chemical vapor deposition (CVD), atomic layer deposition (ALD), or the like. Other acceptable dielectric materials, such as resins, molding compounds, or the like may be utilized. In some embodiments, the gap-fill dielectric 110 is multi-layered. Initially, the gap-fill dielectric 110 may be formed on the second integrated circuit die 50B, such that the gap-fill dielectric 110 buries or covers the second integrated circuit die 50B. Accordingly, the top surface of the gap-fill dielectric 110 may initially be above the back-side of the second integrated circuit die 50B.

A removal process may optionally be performed to level the upper surface of the gap-fill dielectric 110 with the back-side of the second integrated circuit die 50B (e.g., the semiconductor substrate 52B of the second integrated circuit die 50B). The remaining portions of the gap-fill dielectric 110 above the second integrated circuit die 50B are removed. In some embodiments, a planarization process such as a chemical mechanical polish (CMP), an etch-back process, combinations thereof, or the like is utilized. The back-side of the second integrated circuit die 50B may thus be exposed through the gap-fill dielectric 110.

Next, a support substrate 112 is attached to the gap-fill dielectric 110 and the second integrated circuit die 50B. The support substrate 112 may be a glass support substrate, a ceramic support substrate, a semiconductor substrate (e.g., a silicon substrate), a wafer (e.g., a silicon wafer), or the like. The support substrate 112 may provide structural support during subsequent processing steps and in the completed device. The support substrate 112 may be substantially free of any active or passive devices.

The support substrate 112 may be attached to the gap-fill dielectric 110 and the second integrated circuit die 50B with one or more bonding layer(s) (not separately illustrated). The bonding layer(s) are on a surface of the support substrate 112 and a surface of the second integrated circuit die 50B. In some embodiments, the bonding layer(s) include an oxide layer such as a layer of silicon oxide. In some embodiments, the bonding layer(s) include an adhesive, such as a suitable epoxy, a die attach film (DAF), or the like. The bonding layer(s) may be applied to the back-side of the second integrated circuit die 50B; may be applied over the surface of the support substrate 112; and/or the like.

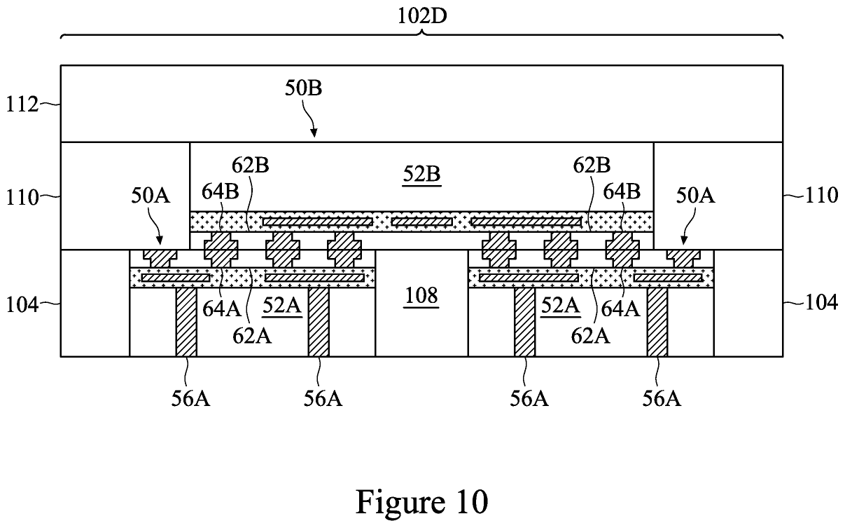

In FIG. 10, a carrier substrate de-bonding is performed to detach (or “de-bond”) the carrier substrate 102 from the first integrated circuit dies 50A. The inner gap-fill dielectric 108, the outer gap-fill dielectric 104, and the back-sides of the first integrated circuit dies 50A are thus exposed. In some embodiments where the bonding layer(s) for the carrier substrate 102 include an oxide layer or an adhesive, the de-bonding includes applying a removal process, such as a grinding process, to the carrier substrate 102 and the bonding layer(s). The structure is then flipped over and placed on a tape (not separately illustrated).

Additionally, the semiconductor substrates 52A of the first integrated circuit dies 50A are thinned to expose the conductive vias 56A of the first integrated circuit dies 50A. The inner gap-fill dielectric 108 and/or the outer gap-fill dielectric 104 may also be thinned. After the thinning, the conductive vias 56A are exposed at the back-sides of the first integrated circuit dies 50A. Exposure of the conductive vias 56A may be accomplished by a thinning process, such as a grinding process, a chemical-mechanical polish (CMP), an etch-back, combinations thereof, or the like. In some embodiments, the exposed surfaces of the semiconductor substrates 52A and the conductive vias 56A are substantially coplanar (within process variations). In other embodiments, a recessing process is performed to recess the inactive surface the semiconductor substrates 52A such that the conductive vias 56A protrude at the back-sides of the first integrated circuit dies 50A. The recessing process may be, e.g., a suitable etch-back process, chemical-mechanical polish (CMP), or the like. In some embodiments, the thinning process for exposing the conductive vias 56A includes a CMP, and the conductive vias 56A protrude at the back-sides of the first integrated circuit dies 50A as a result of dishing that occurs during the CMP. An insulating layer (not separately illustrated) is then formed on the inactive surface of the semiconductor substrates 52A, surrounding the protruding portions of the conductive vias 56A. In some embodiments, the insulating layer is formed of a silicon-containing insulator, such as silicon nitride, silicon oxide, silicon oxynitride, or the like, which may be formed by a suitable deposition method such as CVD, plasma-enhanced CVD (PECVD), high density plasma CVD (HDP-CVD), or the like. Initially, the insulating layer may bury the conductive vias 56A. A removal process can be applied to the various layers to remove excess materials over the conductive vias 56A. The removal process may be a planarization process such as a chemical mechanical polish (CMP), an etch-back, combinations thereof, or the like. After planarization, the exposed surfaces of the conductive vias 56A and the insulating layer are substantially coplanar (within process variations) and are exposed at the back-sides of the first integrated circuit dies 50A.

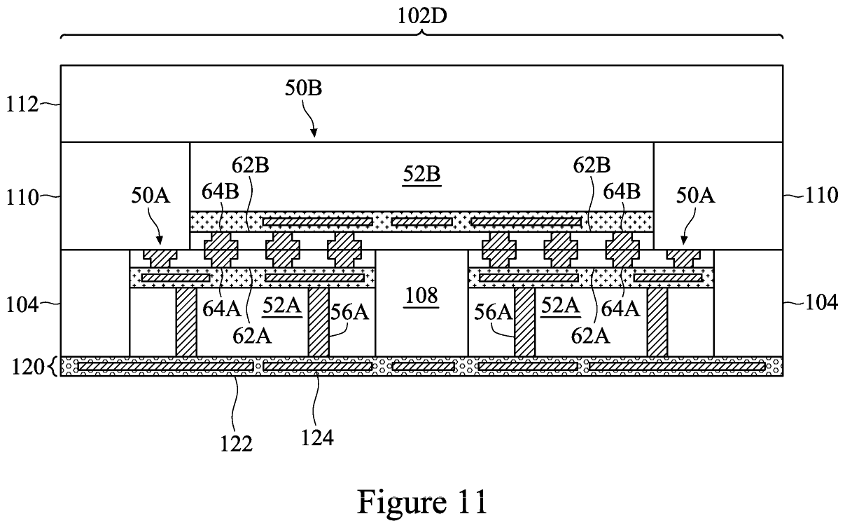

In FIG. 11, a redistribution structure 120 is formed on the back-sides of the first integrated circuit dies 50A, the outer gap-fill dielectric 104, and the inner gap-fill dielectric 108. The redistribution structure 120 may be disposed on the bottom surface of the inner gap-fill dielectric 108, the bottom surface of the outer gap-fill dielectric 104, and the inactive surfaces of the semiconductor substrates 52A. The redistribution structure 120 includes one or more dielectric layer(s) 122 and respective metallization layer(s) 124 (sometimes referred to as redistribution layers or redistribution lines) among the dielectric layer(s) 122. The metallization layer(s) 124 of the redistribution structure 120 are connected to the conductive vias 56A. Specifically, the metallization layer(s) 124 are connected to the first integrated circuit dies 50A and the second integrated circuit die 50B by the conductive vias 56A.

The dielectric layer(s) 122 are formed of suitable dielectric material(s). In some embodiments, the dielectric layer(s) 122 are formed of a polymer, which may be a photosensitive material such as PBO, polyimide, a BCB-based polymer, or the like, which may be patterned using a lithography mask. In other embodiments, the dielectric layer(s) 122 are formed of an oxide such as silicon oxide, PSG, BSG, BPSG; a nitride such as silicon nitride; a combination thereof such as silicon oxynitride; or the like. The dielectric layer(s) 122 may be formed by deposition, spin coating, lamination, the like, or a combination thereof. After each dielectric layer 122 is formed, it is patterned to expose underlying conductive features, e.g. underlying portions of the conductive vias 56A or the metallization layer(s) 124. The patterning may be by an acceptable process, such as by exposing the dielectric layer 122 to light when it is a photosensitive material, or by etching using, for example, an anisotropic etch. If the dielectric layer 122 is formed of a photosensitive material, it can be developed after the exposure.

The metallization layer(s) 124 each include conductive vias and/or conductive lines. The conductive vias extend through the dielectric layer(s) 122, and the conductive lines extend along the dielectric layer(s) 122. As an example to form a metallization layer 124, a seed layer (not separately illustrated) is formed over the respective underlying features. For example, the seed layer can be formed on a respective dielectric layer 122 and in openings through the respective dielectric layer 122. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like, and may be exposed to light for patterning. The pattern of the photoresist corresponds to the metallization layer 124. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form the metallization layer 124.

In FIG. 12, a singulation process is performed along scribe line regions, e.g., between the device region 102D and adjacent device regions (not separately illustrated). The singulation process may include performing a sawing process, a laser cutting process, or the like. The singulation process separates the device region 102D from the adjacent device regions. The resulting, singulated die structure 100 is from the device region 102D. After the singulation process, the outer gap-fill dielectric 104, the gap-fill dielectric 110, the support substrate 112, and the redistribution structure 120 are laterally coterminous.

Optionally, additional features may be formed for attaching the die structure 100 to a package component. In some embodiments, conductive connectors 126 are formed for external connection to the die structure 100. The conductive connectors 126 may be used to connect the redistribution structure 120 to a package component such as an interposer, a package substrate, or the like. The conductive connectors 126 may be formed before or after the die structure 100 is singulated.

The conductive connectors 126 may be formed on under bump metallurgies (not separately illustrated) of the redistribution structure 120. The conductive connectors 126 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 126 may include a conductive material such as solder, copper, aluminum, gold, nickel, silver, palladium, tin, the like, or a combination thereof. In some embodiments, the conductive connectors 126 are formed by initially forming a layer of a reflowable material (e.g., solder) through evaporation, electroplating, printing, solder transfer, ball placement, or the like. Once a layer of solder has been formed on the structure, a reflow may be performed in order to shape the material into the desired bump shapes. In another embodiment, the conductive connectors 126 include metal pillars (such as copper pillars) formed by a sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof, which may be formed by a plating process.

In the cross-sectional view of the resulting die structure 100, the inner gap-fill dielectric 108 is bounded by the first integrated circuit dies 50A in a horizontal direction, and is bounded by the second integrated circuit die 50B and the redistribution structure 120 in a vertical direction. The inner gap-fill dielectric 108 has a width W1 in the horizontal direction and has a height H1 in the vertical direction. The height H1 is large while the width W1 is small. Specifically, the height H1 is larger than the width W1, such that the inner gap-fill dielectric 108 has a high aspect ratio. In some embodiments, the ratio of the height H1 to the width W1 is up to 10. The aspect ratio being greater than 10 may cause difficulty when filling the recess between the first integrated circuit dies 50A with the inner gap-fill dielectric 108; specifically, undesired voids may be formed in the inner gap-fill dielectric 108. In some embodiments, the height H1 is in the range of 10 μm to 300 μm while the width W1 is in the range of 10 μm to 300 μm. The width W1 being greater than 300 μm may cause the inner gap-fill dielectric 108 to occupy excessive package area. The height H1 may be at least half of the height of the second integrated circuit die 50B and the gap-fill dielectric 110.

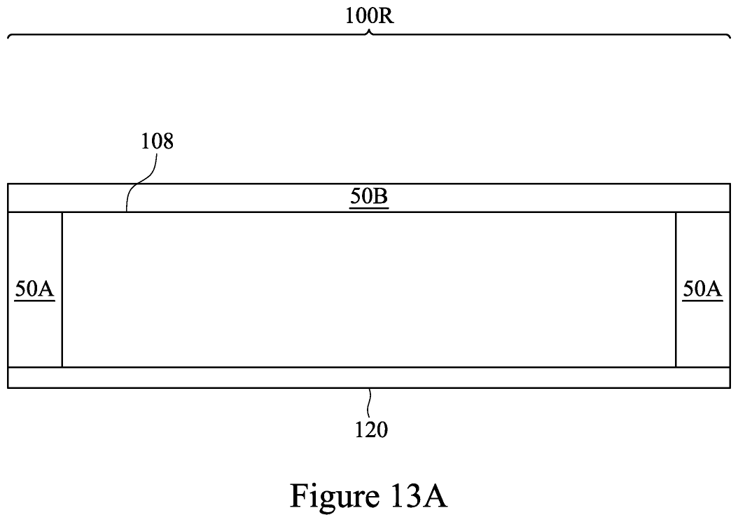

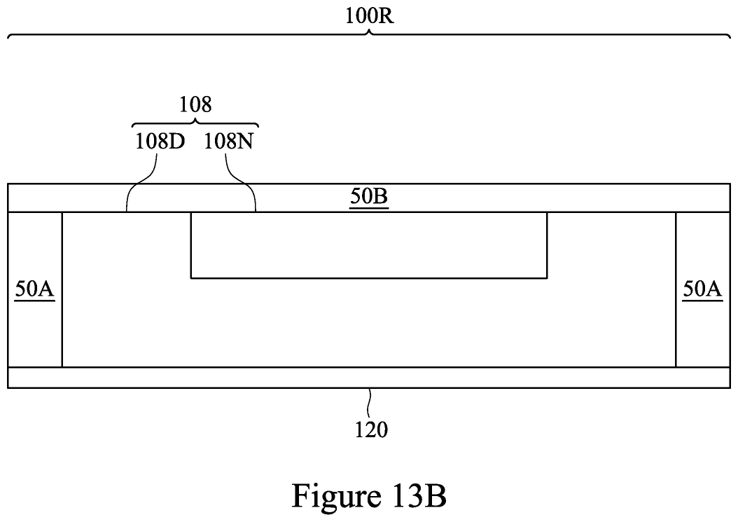

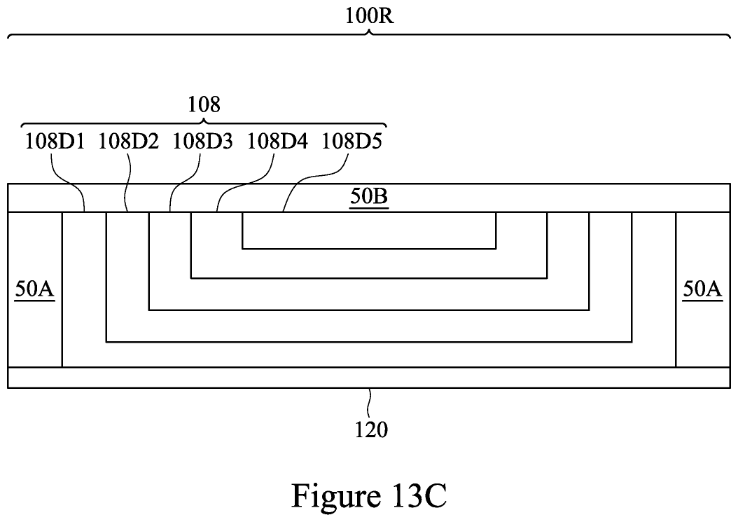

FIGS. 13A-13C are cross-sectional views of die structures 100, in accordance with various embodiments. Detailed views of a region 100R of FIG. 12 are shown for different die structures 100. Specifically, different material stacks that may be utilized for the inner gap-fill dielectric 108 are shown. The inner gap-fill dielectric 108 may be single-layered or may be multi-layered.

In some embodiments, as illustrated in FIG. 13A, the inner gap-fill dielectric 108 is single-layered. Thus, the inner gap-fill dielectric 108 is a single, continuous layer of a gap-fill dielectric material. The gap-fill dielectric material is formed of one of the aforementioned gap-fill dielectric materials that has a matched CTE with the integrated circuit dies 50.

In some embodiments, as illustrated in FIG. 13B, the inner gap-fill dielectric 108 is multi-layered. Thus, the inner gap-fill dielectric 108 includes multiple layers of different gap-fill dielectric materials. In this embodiment, the inner gap-fill dielectric 108 includes a doped layer 108D and an undoped layer 108N. The doped layer 108D is formed of one of the aforementioned gap-fill dielectric materials that has a matched CTE with the integrated circuit dies 50. The undoped layer 108N may be formed of a gap-fill dielectric material that is different than that of the doped layer 108D. In some embodiments, the undoped layer 108N is formed of the same gap-fill dielectric material as the outer gap-fill dielectric 104 (see FIG. 12). The doped layer 108D may be U-shaped, while the undoped layer 108N is on the doped layer 108D. The doped layer 108D may (or may not) have a different thickness than the undoped layer 108N.

The doped layer 108D may have a greater thickness than the undoped layer 108N. The thickness of the doped layer 108D may be at least half the overall height H1 (see FIG. 13) of the inner gap-fill dielectric 108, while the thickness of the undoped layer 108N may be less than half the overall height H1 of the inner gap-fill dielectric 108. Thus, the doped layer 108D may constitute at least half of the height and/or volume of the inner gap-fill dielectric 108.

In some embodiments, as illustrated in FIG. 13C, the inner gap-fill dielectric 108 is multi-layered. Thus, the inner gap-fill dielectric 108 includes multiple layers of different gap-fill dielectric materials. In this embodiment, the inner gap-fill dielectric 108 includes a gradient stack of gap-fill dielectric materials. For example, the inner gap-fill dielectric 108 includes doped layers 108D1-108D5, each of which is formed of one of the aforementioned gap-fill dielectric materials that has a matched CTE with the integrated circuit dies 50. In embodiments where the inner gap-fill dielectric 108 includes impurity-containing silicon-based dielectric materials, each of the doped layers 108D1-108D5 stacked in a direction extending from the redistribution structure 120 to the second integrated circuit die 50B has a decreasing concentration of a non-silicon impurity. Thus, the upper doped layers have lower impurity concentrations than the lower doped layers. In embodiments where the inner gap-fill dielectric 108 includes transition metal oxides, each of the doped layers 108D1-108D5 stacked in a direction extending from the redistribution structure 120 to the second integrated circuit die 50B has a decreasing concentration of a transition metal. Thus, the upper doped layers have lower transition metal concentrations than the lower doped layers. The lower ones of the doped layers 108D1-108D5 may be U-shaped. Each of the doped layers 108D1-108D5 may (or may not) have a different thickness than others of the doped layers 108D1-108D5.

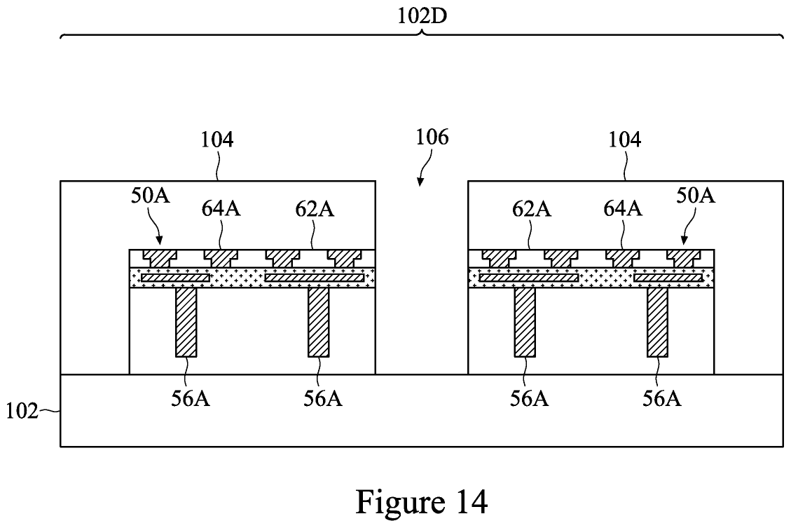

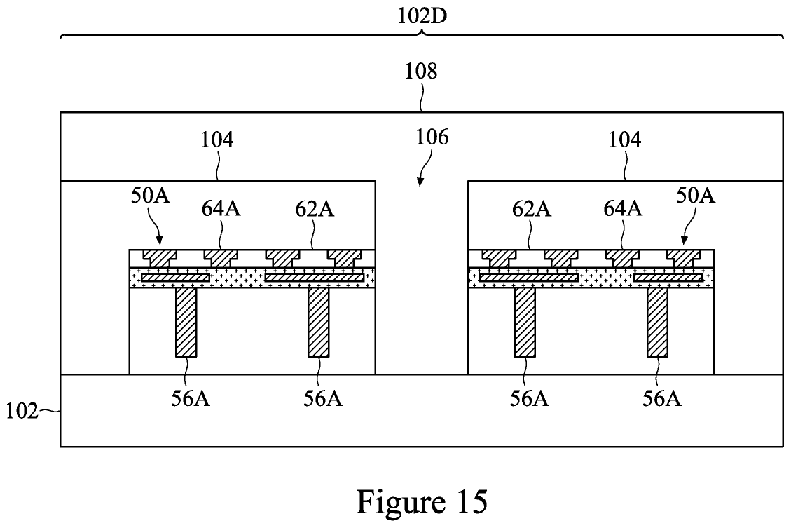

FIGS. 14-15 are cross-sectional views of intermediate stages in the manufacturing of a die structure 100, in accordance with some other embodiments. This embodiment is similar to the embodiment of FIGS. 2-12, except a removal process for the outer gap-fill dielectric 104 is not performed before the formation of the inner gap-fill dielectric 108.

In FIG. 14, and proceeding from the step of FIG. 3, the outer gap-fill dielectric 104 is patterned to remove portions of the outer gap-fill dielectric 104 between the first integrated circuit dies 50A, thus forming a recess 106 between the first integrated circuit dies 50A. The recess 106 may be formed in a similar manner as previously described for FIG. 5. In this embodiment, the removal process described for FIG. 4 is omitted. If the outer gap-fill dielectric 104 has sufficient flatness after it is initially formed, the removal process may be omitted. Thus, the outer gap-fill dielectric 104 covers the front-sides of the first integrated circuit dies 50A during the formation of the recess 106.

In FIG. 15, an inner gap-fill dielectric 108 is formed in the recess 106 and over the outer gap-fill dielectric 104. The inner gap-fill dielectric 108 may be formed in a similar manner as previously described for FIG. 6. Since the outer gap-fill dielectric 104 covers the front-sides of the first integrated circuit dies 50A, the inner gap-fill dielectric 108 does not contact the front-sides of the first integrated circuit dies 50A in this embodiment. A removal process may then be performed to level the upper surface of the inner gap-fill dielectric 108 with the front-sides of the first integrated circuit dies 50A (e.g., the dielectric layers 62A of the first integrated circuit dies 50A) and the upper surface of the outer gap-fill dielectric 104. Subsequently, appropriate steps as previously described may be performed to complete the manufacturing of a die structure 100 (see FIG. 12).

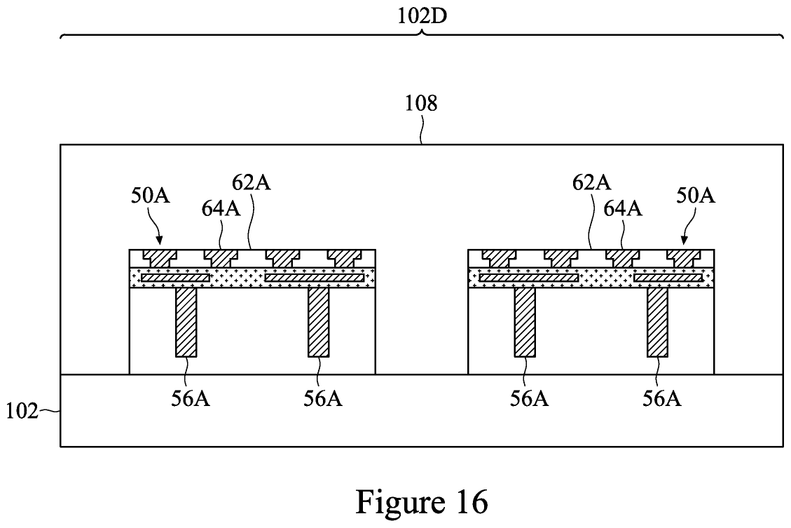

FIGS. 16-19 are cross-sectional views of intermediate stages in the manufacturing of a die structure 100, in accordance with some other embodiments. This embodiment is similar to the embodiment of FIGS. 2-12, except the inner gap-fill dielectric 108 is formed before the outer gap-fill dielectric 104.

In FIG. 16, and proceeding from the step of FIG. 2, an inner gap-fill dielectric 108 is formed over and around the first integrated circuit dies 50A. The inner gap-fill dielectric 108 may be formed in a similar manner as previously described for FIG. 6.

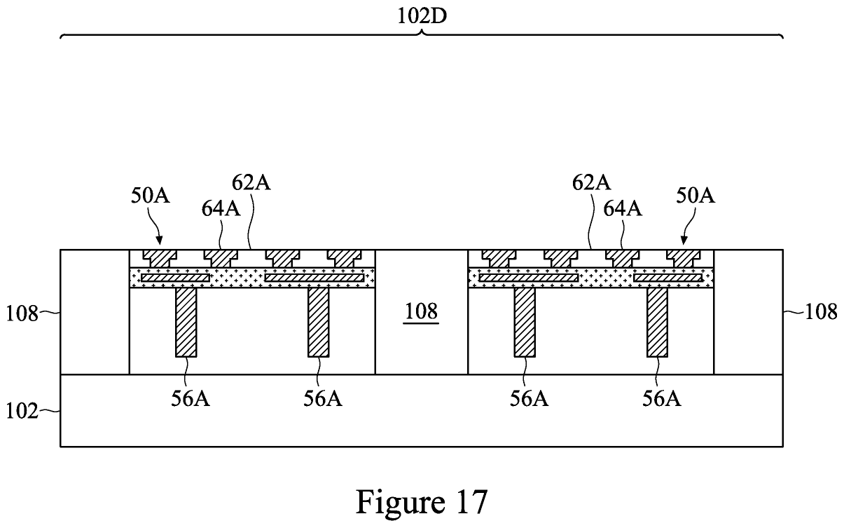

In FIG. 17, a removal process may optionally be performed to level the upper surface of the inner gap-fill dielectric 108 with the front-sides of the first integrated circuit dies 50A. If the inner gap-fill dielectric 108 has sufficient flatness after it is initially formed, this removal process may be omitted. The removal process may be performed in a similar manner as previously described for FIG. 7.

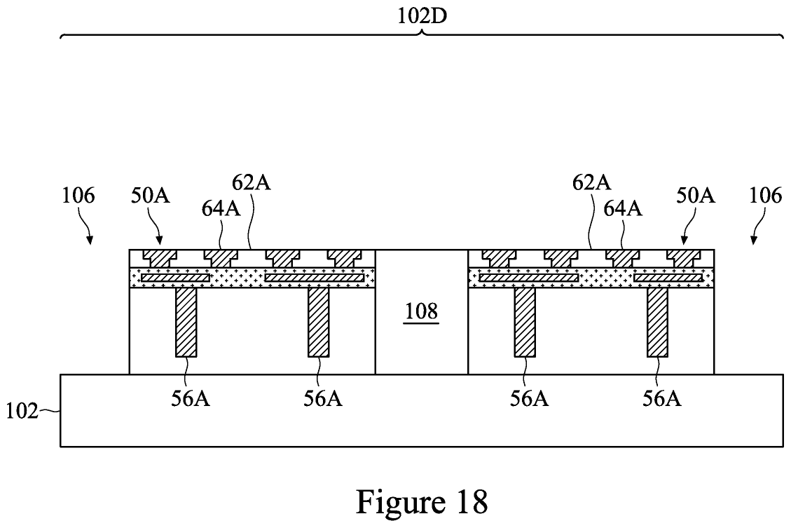

In FIG. 18, the inner gap-fill dielectric 108 is patterned to remove portions of the inner gap-fill dielectric 108 around the first integrated circuit dies 50A (collectively), thus forming a recess 106 around the first integrated circuit dies 50A. The recess 106 may extend around the dies first integrated circuit dies 50A (collectively) in a top-down view (not separately illustrated). Initially, the inner gap-fill dielectric 108 may be in the outer portion and the inner portion of the device region 102D. The patterning removes the inner gap-fill dielectric 108 from the outer portion of the device region 102D, such that the inner gap-fill dielectric 108 remains in the inner portion of the device region 102D. The inner gap-fill dielectric 108 may be patterned using acceptable photolithography and etching techniques.

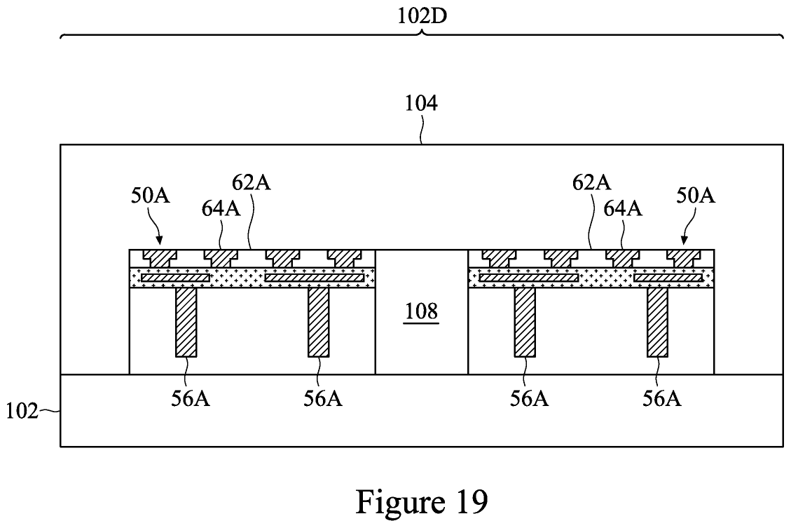

In FIG. 19, an outer gap-fill dielectric 104 is formed in the recess 106 and over the inner gap-fill dielectric 108 and the first integrated circuit dies 50A. The outer gap-fill dielectric 104 may be formed in a similar manner as previously described for FIG. 3. A removal process may then be performed to level the upper surface of the outer gap-fill dielectric 104 with the front-sides of the first integrated circuit dies 50A (e.g., the dielectric layers 62A of the first integrated circuit dies 50A) and the upper surface of the inner gap-fill dielectric 108. Subsequently, appropriate steps as previously described may be performed to complete the manufacturing of a die structure 100 (see FIG. 12).

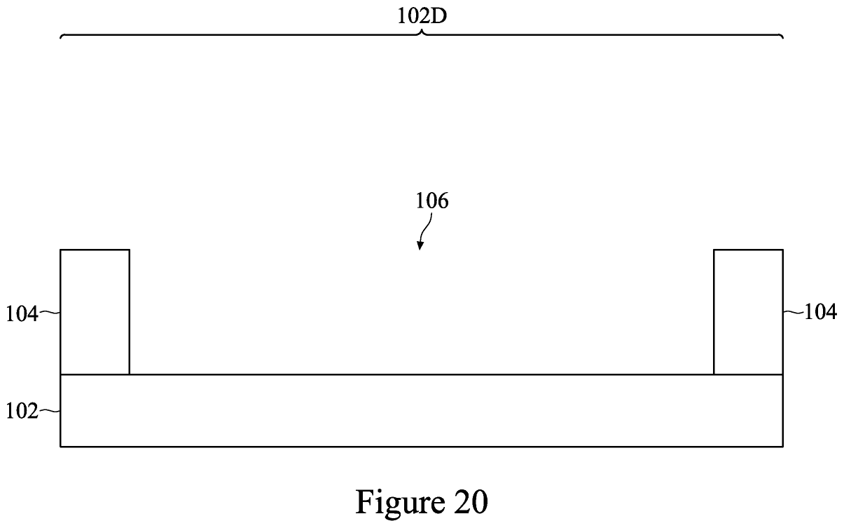

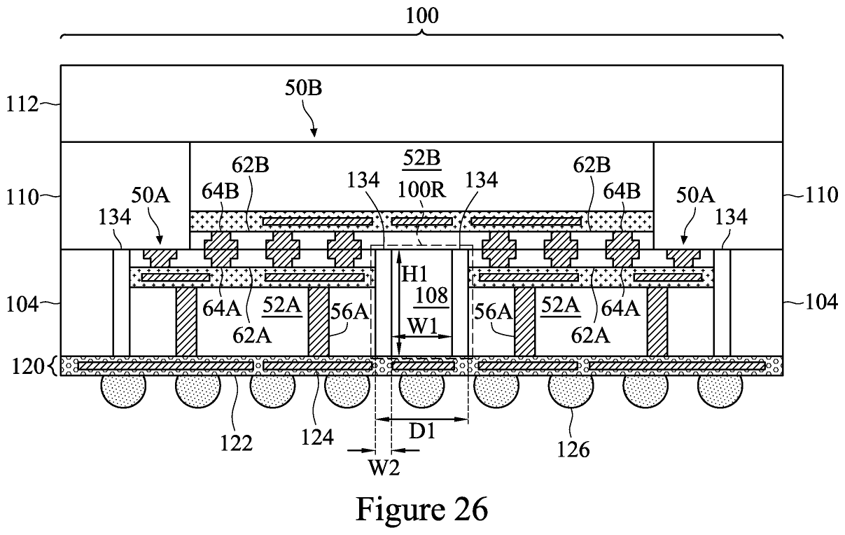

FIGS. 20-26 are cross-sectional views of intermediate stages in the manufacturing of a die structure 100 (see FIG. 26), in accordance with some other embodiments. This embodiment is similar to the embodiment of FIGS. 2-12, except the first integrated circuit dies 50A are attached to a carrier substrate 102 after each of the outer gap-fill dielectric 104 and the inner gap-fill dielectric 108 are formed.

In FIG. 20, an outer gap-fill dielectric 104 is formed over a carrier substrate 102. The outer gap-fill dielectric 104 may be formed in a similar manner as previously described for FIG. 3. The outer gap-fill dielectric 104 is then patterned to remove portions of the outer gap-fill dielectric 104 from the inner portion of the device region 102D, thus forming a recess 106 in the inner portion of the device region 102D. The outer gap-fill dielectric 104 may be patterned using acceptable photolithography and etching techniques.

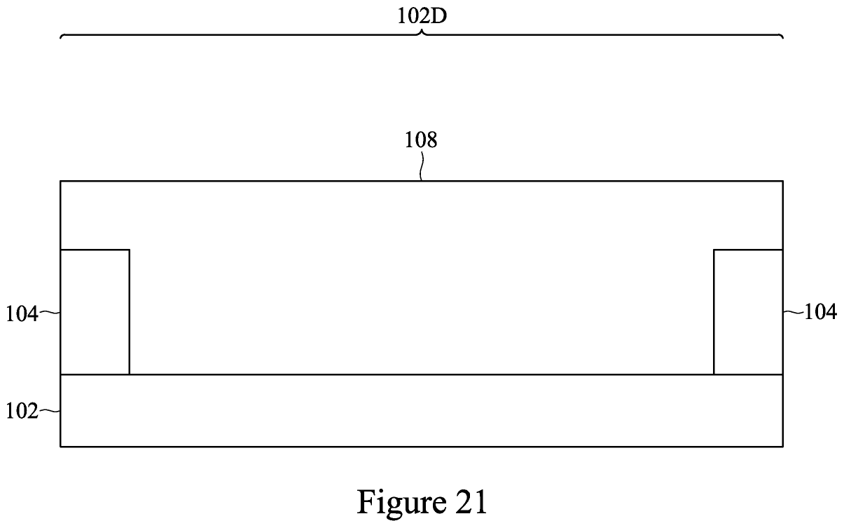

In FIG. 21, an inner gap-fill dielectric 108 is formed in the recess 106 and over the outer gap-fill dielectric 104. The inner gap-fill dielectric 108 may be formed in a similar manner as previously described for FIG. 6.

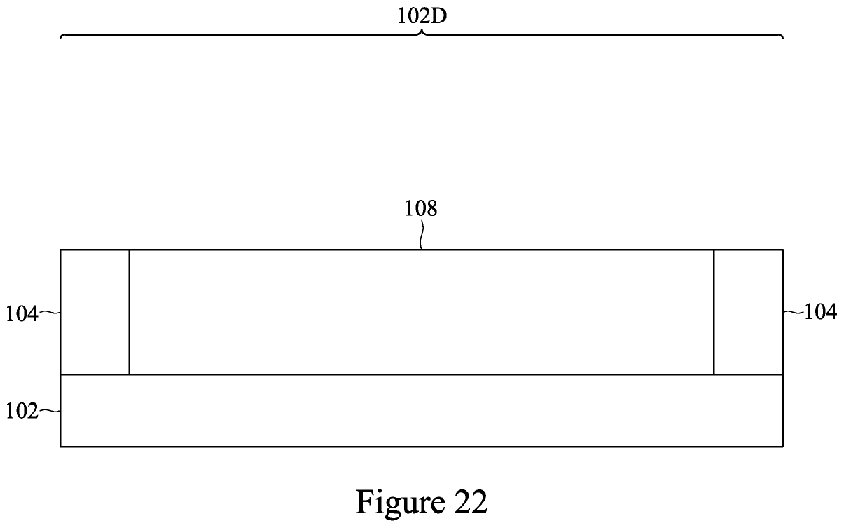

In FIG. 22, a removal process is performed to level the upper surface of the inner gap-fill dielectric 108 with the upper surface of the outer gap-fill dielectric 104. The removal process may be performed in a similar manner as previously described for FIG. 7. The remaining portions of the inner gap-fill dielectric 108 above the outer gap-fill dielectric 104 are removed. In some embodiments, a planarization process such as a chemical mechanical polish (CMP), an etch-back process, combinations thereof, or the like is utilized.

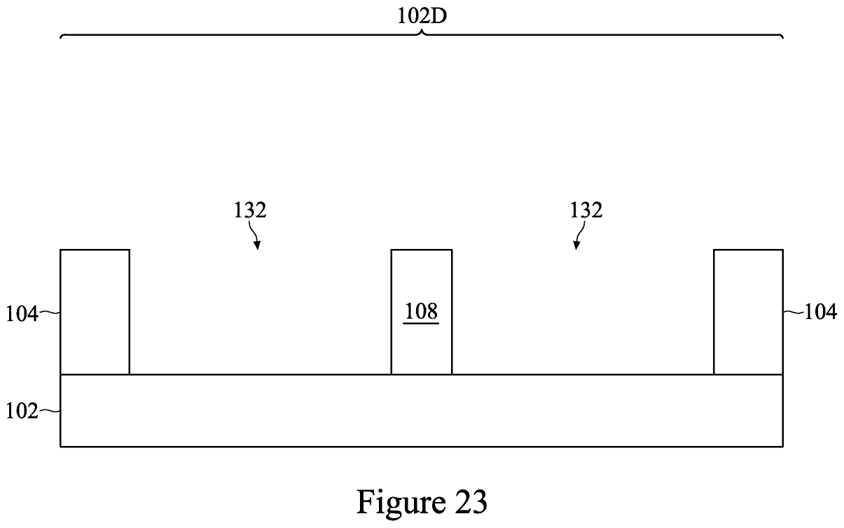

In FIG. 23, the inner gap-fill dielectric 108 and/or the outer gap-fill dielectric 104 are patterned, thus forming recesses 132. The recesses 132 may expose the carrier substrate 102. Integrated circuit dies will be subsequently placed in the recesses 132. The remaining portion of the inner gap-fill dielectric 108 is between the recesses 132, and the remaining portion of the outer gap-fill dielectric 104 is around the recesses 132 (collectively). The inner gap-fill dielectric 108 and/or the outer gap-fill dielectric 104 may be patterned using acceptable photolithography and etching techniques.

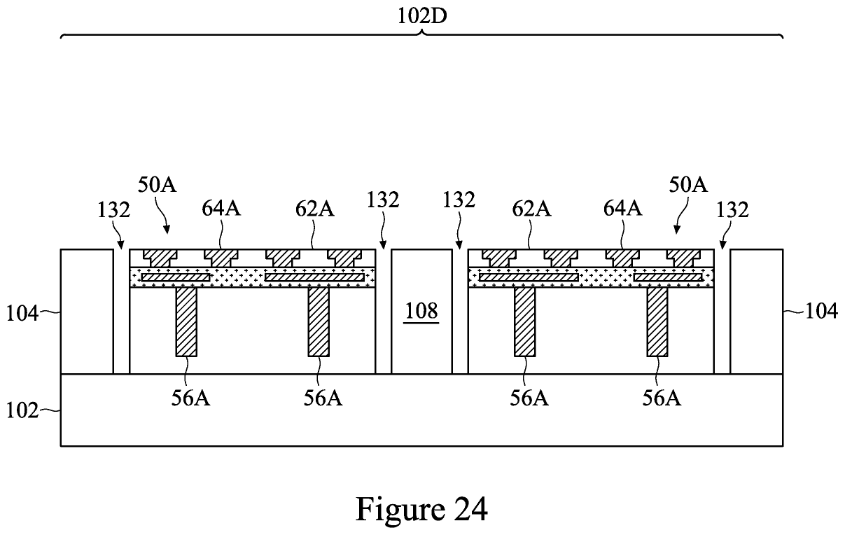

In FIG. 24, first integrated circuit dies 50A are placed in the recesses 132, and are attached to the carrier substrate 102 in a face-up manner, such that the back-sides of first integrated circuit dies 50A are attached to the carrier substrate 102. The first integrated circuit dies 50A may be attached to the carrier substrate 102 in a similar manner as previously described for FIG. 2. Each first integrated circuit die 50A may partially fill a recess 132, such that the remaining portions of the recess 132 are between the first integrated circuit dies 50A and the inner gap-fill dielectric 108 or the outer gap-fill dielectric 104.

In this embodiment, the inner gap-fill dielectric 108 is formed after the outer gap-fill dielectric 104. In other embodiments, the inner gap-fill dielectric 108 is formed before the outer gap-fill dielectric 104, in a similar manner as previously described for FIGS. 16-19.

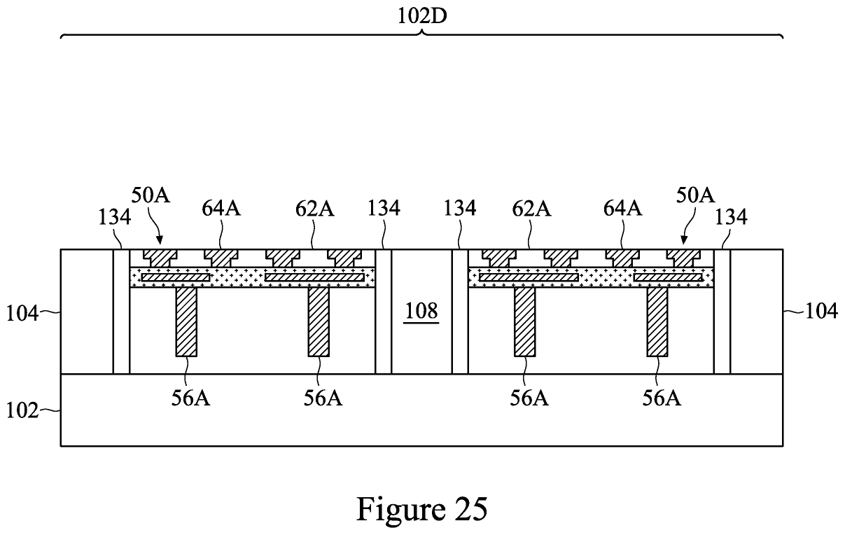

In FIG. 25, spacers 134 are formed in the recesses 132. The spacers 134 are dielectric features that fill the gaps between the first integrated circuit dies 50A and the inner gap-fill dielectric 108 or the outer gap-fill dielectric 104. In this embodiment, the spacers 134 separate the inner gap-fill dielectric 108 from the inner sidewalls of the first integrated circuit dies 50A. The spacers 134 may be formed of one or more dielectric materials. Acceptable gap-fill dielectric materials include oxides such as silicon oxide, phosphosilicate glass (PSG), borosilicate glass (BSG), boron-doped phosphosilicate glass (BPSG), a tetraethyl orthosilicate (TEOS) based oxide, or the like; nitrides such as silicon nitride or the like; combinations thereof; or the like, which may be formed by a suitable deposition process such as chemical vapor deposition (CVD), atomic layer deposition (ALD), or the like. Other acceptable dielectric materials, such as resins, molding compounds, or the like may be utilized. In some embodiments, the spacers 134 are multi-layered. As subsequently described in greater detail, the material of the spacers 134 may be different than the outer gap-fill dielectric 104. Initially, the material of the spacers 134 may be formed on the outer gap-fill dielectric 104, the inner gap-fill dielectric 108, and the first integrated circuit dies 50A, such that the spacer material buries or covers the first integrated circuit dies 50A. A removal process may then be performed to level the upper surfaces of the spacers 134 with the front-sides of the first integrated circuit dies 50A (e.g., the dielectric layers 62A of the first integrated circuit dies 50A), the upper surface of the outer gap-fill dielectric 104, and the upper surface of the inner gap-fill dielectric 108. In some embodiments, a planarization process such as a chemical mechanical polish (CMP), an etch-back process, combinations thereof, or the like is utilized.

In FIG. 26, appropriate steps as previously described may be performed to complete the manufacturing of a die structure 100 (see FIG. 12). In this embodiments, the second integrated circuit die 50B also overlaps the spacers 134 between the first integrated circuit dies 50A.

In the cross-sectional view of the resulting die structure 100, the inner gap-fill dielectric 108 is bounded by the spacers 134 in a horizontal direction, and is bounded by the second integrated circuit die 50B and the redistribution structure 120 in a vertical direction. The height H1 of the inner gap-fill dielectric 108 is larger than the width W1 of the inner gap-fill dielectric 108, such that the inner gap-fill dielectric 108 has a high aspect ratio. The first integrated circuit dies 50A are separated by a distance D1, which is greater than the width W1 on account of the spacers 134 being present. In some embodiments, the distance D1 is in the range of 10 μm to 300 μm. Each spacer 134 has a width W2, which is less than the distance D1. The width W2 may be at least one hundredth of the distance D1 and at most one tenth of the distance D1. In some embodiments, the width W2 is in the range of 1 μm to 30 μm.

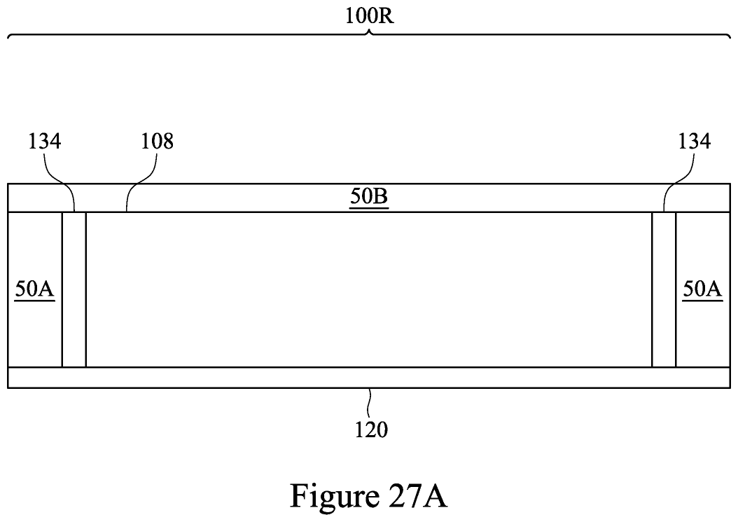

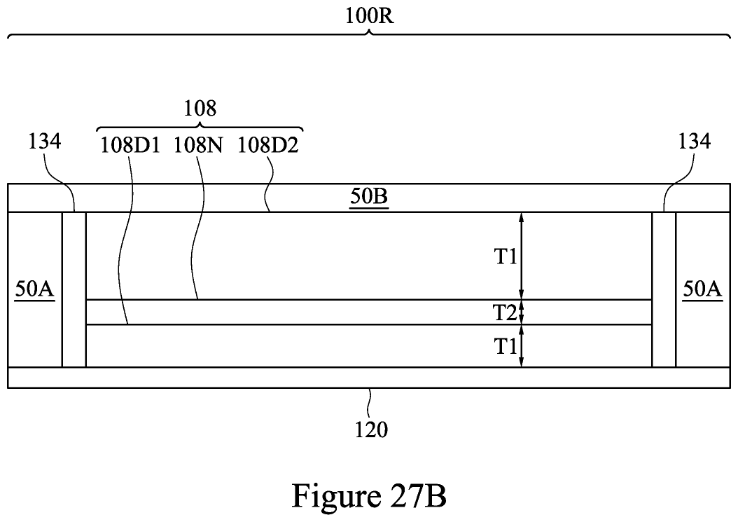

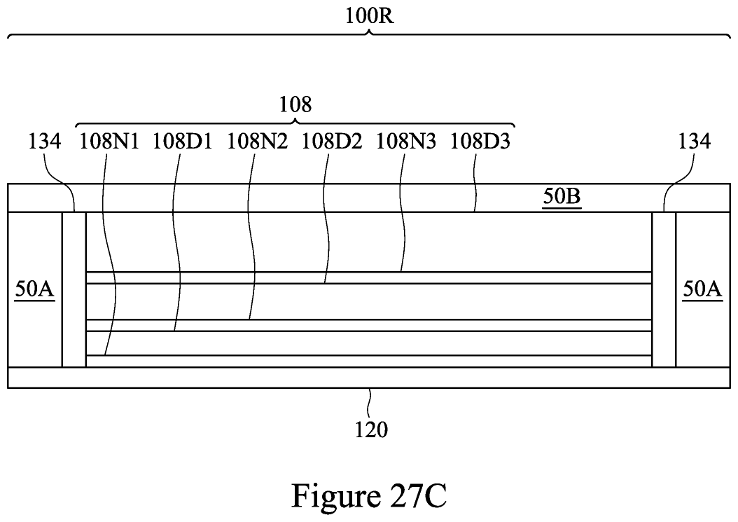

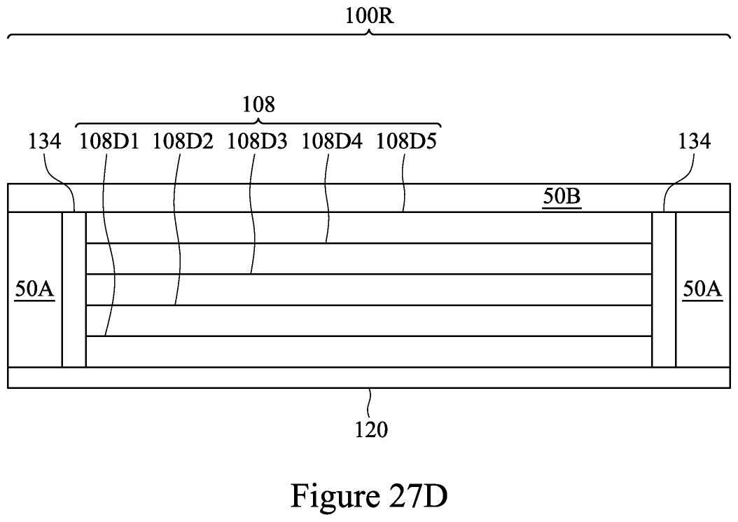

FIGS. 27A-27D are cross-sectional views of die structures 100, in accordance with various embodiments. Detailed views of a region 100R of FIG. 26 are shown for different die structures 100. Specifically, different material stacks that may be utilized for the inner gap-fill dielectric 108 are shown. The inner gap-fill dielectric 108 may be single-layered or may be multi-layered.

In some embodiments, as illustrated in FIG. 27A, the inner gap-fill dielectric 108 is single-layered. Thus, the inner gap-fill dielectric 108 is a single, continuous layer of a gap-fill dielectric material. The gap-fill dielectric material is formed of one of the aforementioned gap-fill dielectric materials that has a matched CTE with the integrated circuit dies 50.

In some embodiments, as illustrated in FIG. 27B, the inner gap-fill dielectric 108 is multi-layered. Thus, the inner gap-fill dielectric 108 includes multiple layers of different gap-fill dielectric materials. In this embodiment, the inner gap-fill dielectric 108 includes a pair of doped layers 108D1, 108D2 and an undoped layer 108N between the doped layers 108D1, 108D2. The doped layers 108D1, 108D2 are formed of one of the aforementioned gap-fill dielectric materials that has a matched CTE with the integrated circuit dies 50. The undoped layer 108N may be formed of a gap-fill dielectric material that is different than that of the doped layers 108D1, 108D2. In some embodiments, the undoped layer 108N is formed of the same gap-fill dielectric material as the outer gap-fill dielectric 104 (see FIG. 26) and/or the same material as the spacers 134. The undoped layer 108N may (or may not) have a different thickness than the doped layers 108D1, 108D2.

Each of the doped layers 108D1, 108D2 may have a thickness T1 and the undoped layer 108N may have a thickness T2. The thickness T1 of the first doped layer 108D1 may be different than the thickness T1 of the second doped layer 108D2. The thickness T1 of the first doped layer 108D1 and the thickness T1 of the second doped layer 108D2 may each be greater than the thickness T2 of the undoped layer 108N. The thickness T1 of each doped layer 108D1, 108D2 may be at least one tenth of the overall height H1 (see FIG. 26) of the inner gap-fill dielectric 108. The sum of the thicknesses T1 of the doped layers 108D1, 108D2 may be at least half the overall height H1 of the inner gap-fill dielectric 108, while the thickness T2 of the undoped layer 108N may be less than half the overall height H1 of the inner gap-fill dielectric 108. Thus, the doped layers 108D1, 108D2 may constitute at least half of the height and/or volume of the inner gap-fill dielectric 108.

In some embodiments, as illustrated in FIG. 27C, the inner gap-fill dielectric 108 is multi-layered. Thus, the inner gap-fill dielectric 108 includes multiple layers of different gap-fill dielectric materials. In this embodiment, the inner gap-fill dielectric 108 includes alternating doped layers 108D1, 108D2, 108D3 and undoped layers 108N1, 108N2, 108N3. Each doped layer may be on an underlying undoped layer. The doped layers 108D1, 108D2, 108D3 are formed of one of the aforementioned gap-fill dielectric materials that has a matched CTE with the integrated circuit dies 50. The undoped layers 108N1, 108N2, 108N3 may be formed of a gap-fill dielectric material that is different than that of the doped layers 108D1, 108D2, 108D3. The undoped layers 108N1, 108N2, 108N3 may (or may not) have different thicknesses than the doped layers 108D1, 108D2, 108D3.

The thickness of each doped layer may be different (e.g., greater) than the thickness of its underlying undoped layer. Additionally each doped layer may have a different thickness than others of the doped layers. The thickness of each doped layer 108D1, 108D2, 108D3 may be at least one tenth of the overall height H1 (see FIG. 26) of the inner gap-fill dielectric 108. The sum of the thicknesses of the doped layers 108D1, 108D2, 108D3 may be at least half the overall height H1 of the inner gap-fill dielectric 108, while the sum of the thicknesses of the undoped layers 108N1, 108N2, 108N3 may be less than half the overall height H1 of the inner gap-fill dielectric 108. Thus, the doped layers 108D1, 108D2, 108D3 may constitute at least half of the height and/or volume of the inner gap-fill dielectric 108.

In some embodiments, as illustrated in FIG. 27D, the inner gap-fill dielectric 108 is multi-layered. Thus, the inner gap-fill dielectric 108 includes multiple layers of different gap-fill dielectric materials. In this embodiment, the inner gap-fill dielectric 108 includes a gradient stack of gap-fill dielectric materials, similar to that described for FIG. 13C. Each of the doped layers 108D1-108D5 may be flat.

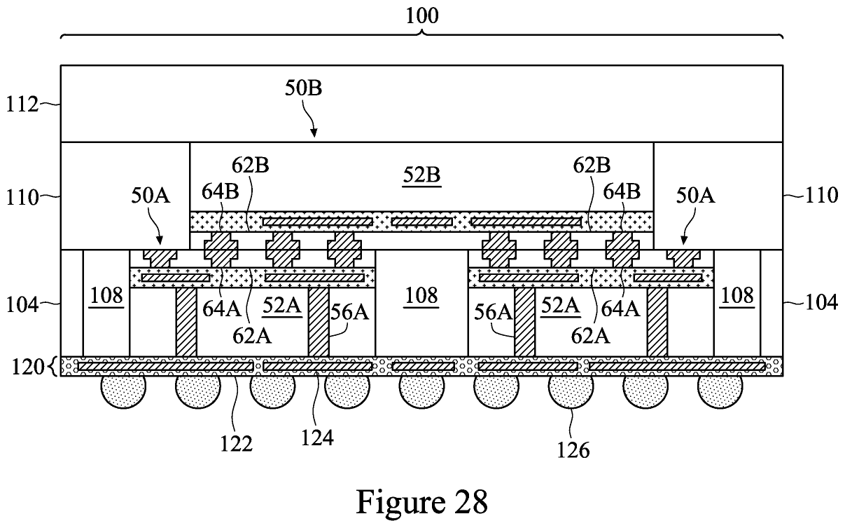

FIG. 28 is a cross-sectional view of a die structure 100, in accordance with some other embodiments. This embodiment is similar to the embodiment of FIGS. 12, except the inner gap-fill dielectric 108 is formed (laterally) around all sides of the first integrated circuit dies 50A. The outer gap-fill dielectric 104 is formed (laterally) around all sides of the inner gap-fill dielectric 108. Thus, the first integrated circuit dies 50A are laterally surrounded by one of the aforementioned gap-fill dielectric materials that has a matched CTE with the integrated circuit dies 50. It should be appreciated that the inner gap-fill dielectric 108 may also be formed (laterally) around all sides of the first integrated circuit dies 50A in the die structure 100 of FIG. 26.

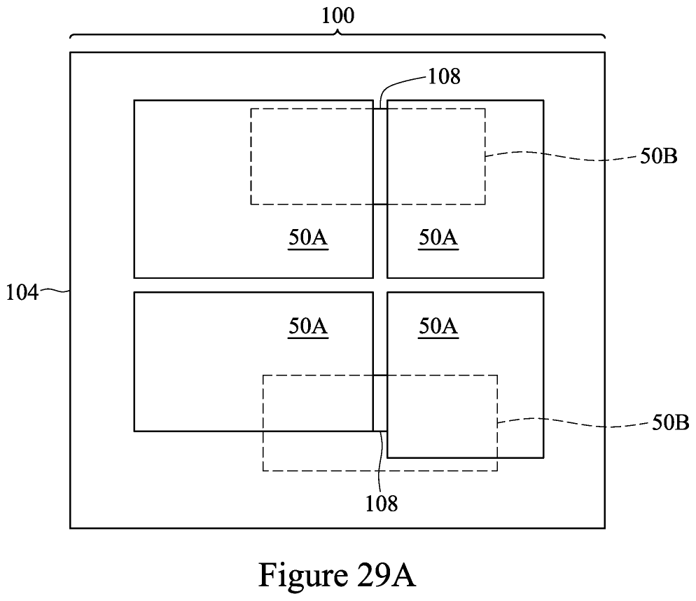

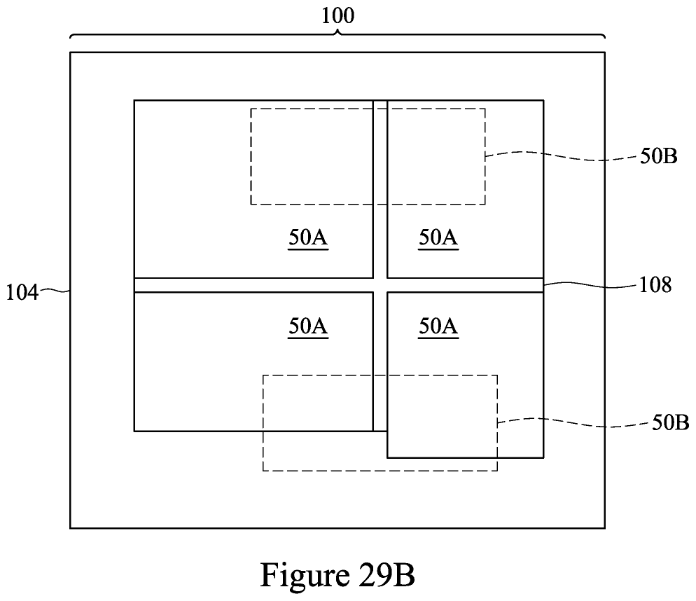

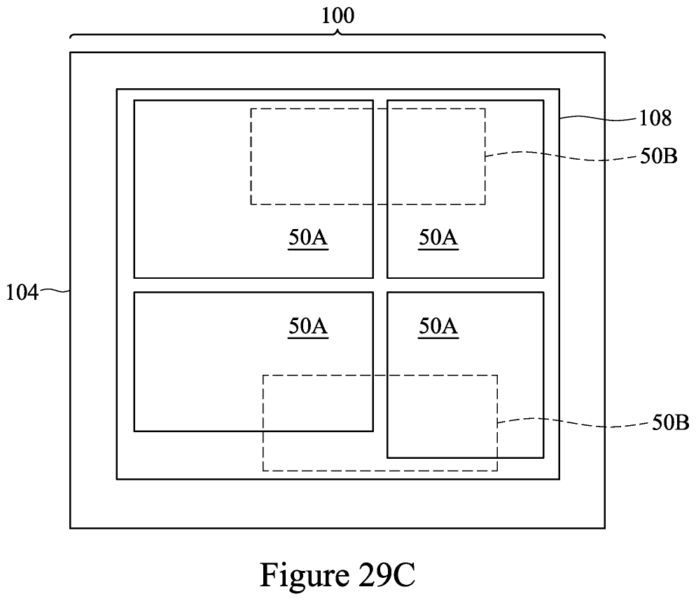

FIGS. 29A-29C are top-down views of die structures 100, in accordance with various embodiments. Features of one layer of the die structures 100 (e.g., the layer containing the first integrated circuit dies 50A) are shown with solid lines, while features of an overlying layer of the die structures 100 (e.g., the layer containing the second integrated circuit dies 50B) are shown with dotted lines.

In some embodiments, as shown in FIG. 29A, the inner gap-fill dielectric 108 is disposed in some areas between the first integrated circuit dies 50A, and specifically, in portions of areas beneath the second integrated circuit dies 50B. The portions of the areas between the between the first integrated circuit dies 50A that are not beneath the second integrated circuit dies 50B may be filled by the outer gap-fill dielectric 104. Thus, the outer gap-fill dielectric 104 extends along the outer sidewalls of the first integrated circuit dies 50A as well as the inner sidewalls of the first integrated circuit dies 50A. The die structures 100 of FIGS. 12 and 26 may have such a layout.

In some embodiments, as shown in FIG. 29B, the inner gap-fill dielectric 108 is disposed in all areas between the first integrated circuit dies 50A, including in areas that are not beneath the second integrated circuit dies 50B. Thus, the outer gap-fill dielectric 104 extends along the outer sidewalls of the first integrated circuit dies 50A, but does not extend along the inner sidewalls of the first integrated circuit dies 50A. The die structures 100 of FIGS. 12 and 26 may have such a layout.

In some embodiments, as shown in FIG. 29C, the inner gap-fill dielectric 108 is disposed in all areas between the first integrated circuit dies 50A, as well as along the outer sidewalls of the first integrated circuit dies 50A. The outer gap-fill dielectric 104 is disposed along the outer sidewalls of the inner gap-fill dielectric 108. The die structure 100 of FIG. 28 may have such a layout.

FIG. 30 is a cross-sectional view of a die structure 100, in accordance with some other embodiments. This embodiment is similar to the embodiment of FIG. 12, except the die structure 100 includes an additional layer of dies, e.g., a third integrated circuit die 50C. It should be appreciated that the die structures 100 of FIG. 26 or 28 could also have a third integrated circuit die 50C. The third integrated circuit die 50C is attached to the second integrated circuit die 50B, such that the front-side of the third integrated circuit die 50C faces the back-side of the second integrated circuit die 50B. Further, a gap-fill dielectric 140 is formed around the third integrated circuit die 50C. The support substrate 112 is attached to the gap-fill dielectric 140 and the third integrated circuit die 50C.

When the die structure 100 includes the third integrated circuit die 50C, the second integrated circuit die 50B may further include conductive vias 56B, a dielectric layer 66B at the back-side of the second integrated circuit die 50B, and die connectors 68B that extend through the dielectric layer 66B. The dielectric layer 66B may be formed of a similar material as the dielectric layer 62B. The die connectors 68B are connected to the metallization layer(s) of the interconnect structure 54B through the conductive vias 56B.

The third integrated circuit die 50C may be bonded to the second integrated circuit die 50B by hybrid bonding. In hybrid bonding, the dielectric layer 62C of the third integrated circuit die 50C is bonded to the dielectric layer 66B of the second integrated circuit die 50B through dielectric-to-dielectric bonding, without using any adhesive material (e.g., die attach film), and the die connectors 64C of the third integrated circuit die 50C are bonded to the die connectors 68B of the second integrated circuit die 50B through metal-to-metal bonding, without using any reflowable material (e.g., solder).

Although not separately illustrated, it should be appreciated that the die structure 100 of FIG. 30 may include multiple second integrated circuit dies 50B. In such an embodiment, an inner gap-fill dielectric may be formed between the second integrated circuit dies 50B, similar to how the inner gap-fill dielectric 108 is formed between the first integrated circuit dies 50A. The inner gap-fill dielectric between the second integrated circuit dies 50B is formed of one of the aforementioned gap-fill dielectric materials that has a matched CTE with the integrated circuit dies 50, and may underly the third integrated circuit die 50C.

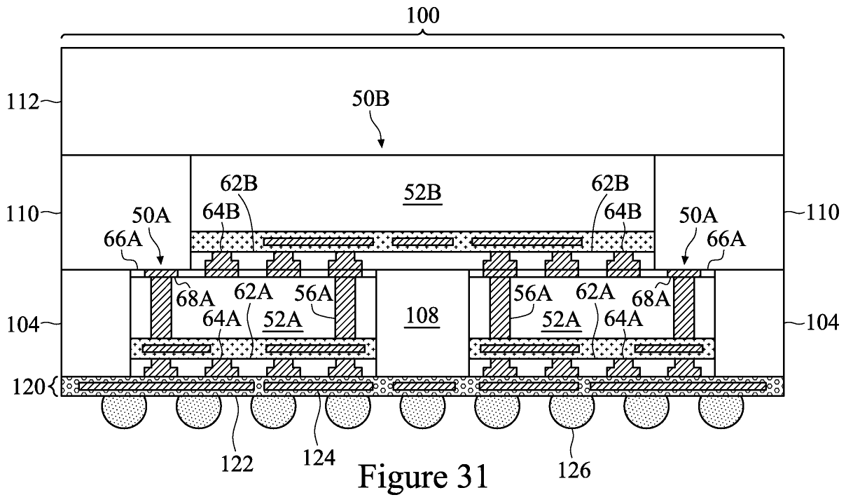

FIG. 31 is a cross-sectional view of a die structure 100, in accordance with some other embodiments. This embodiment is similar to the embodiment of FIG. 12, except the second integrated circuit die 50B and the first integrated circuit dies 50A are directly bonded in a face-to-back manner, such that the front-side of the second integrated circuit die 50B is bonded to the back-sides of the first integrated circuit dies 50A. Each first integrated circuit die 50A further includes a dielectric layer 66A at the back-side of the first integrated circuit die 50A, and die connectors 68A that extend through the dielectric layer 66A. The dielectric layers 66A may be formed of a similar material as the dielectric layers 62A. The die connectors 68A are connected to the metallization layer(s) of the interconnect structure 54A through the conductive vias 56A. The dielectric layer 62B of the second integrated circuit die 50B is bonded to the dielectric layers 66A of the first integrated circuit dies 50A through dielectric-to-dielectric bonding, without using any adhesive material (e.g., die attach film), and the die connectors 64B of the second integrated circuit die 50B are bonded to the die connectors 68A of the first integrated circuit dies 50A through metal-to-metal bonding, without using any reflowable material (e.g., solder).

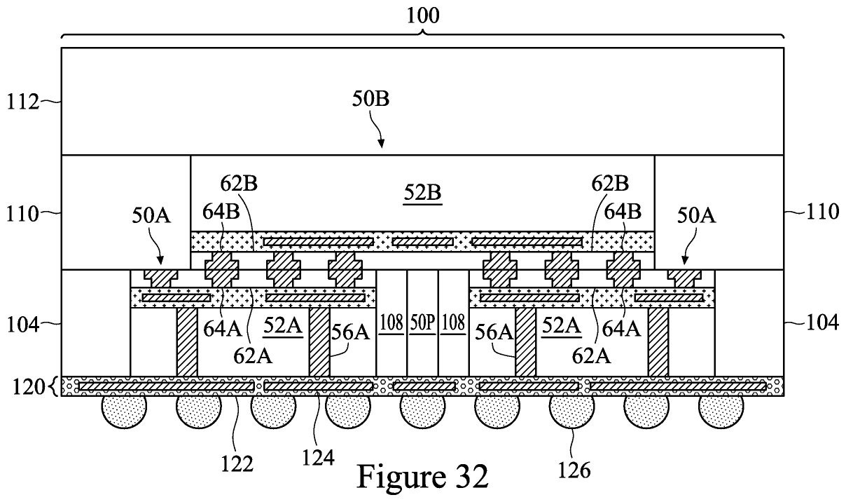

FIG. 32 is a cross-sectional view of a die structure 100, in accordance with some other embodiments. This embodiment is similar to the embodiment of FIG. 12, except the die structure 100 further includes a passive device 50P. The passive device 50P may be disposed in the inner gap-fill dielectric 108, between the first integrated circuit dies 50A.

The passive device 50P may be an integrated passive device (IPD), a power management integrated circuit (PMIC), an integrated voltage regulator (IVR), or the like. The passive device 50P includes a substrate, which can be similar to the semiconductor substrate 52 described for FIG. 1, but includes passive devices (e.g., resistors, capacitors, inductors, etc.) and may be free of active devices (e.g., transistors, diodes, etc.). The passive device 50P may be connected to the front-side of the second integrated circuit die 50B, such that die connectors or electrodes (not separately illustrated) of the passive device 50P face the second integrated circuit die 50B. The passive device 50P may be connected to the redistribution structure 120, such that die connectors or electrodes (not separately illustrated) of the passive device 50P face the redistribution structure 120.

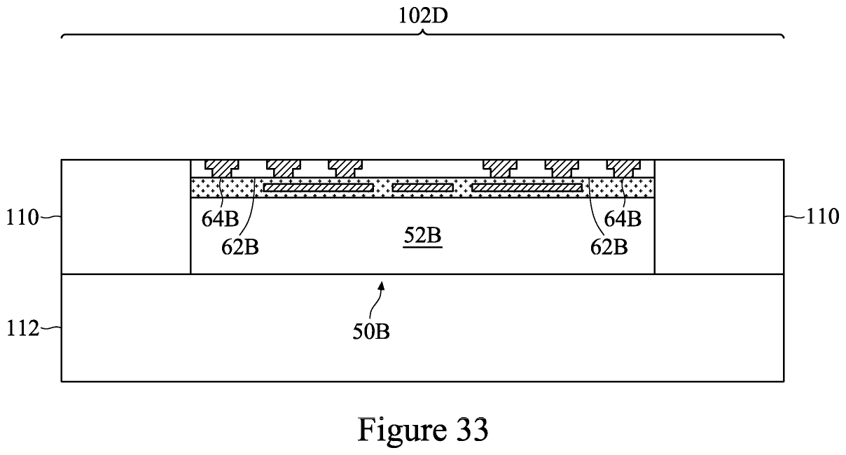

FIGS. 33-36 are cross-sectional views of intermediate stages in the manufacturing of a die structure 100, in accordance with some other embodiments. This embodiment is similar to the embodiment of FIGS. 2-12, except the layers of the die structure 100 are formed in reverse order. Specifically, a second integrated circuit die 50B is initially placed on a carrier substrate, and first integrated circuit dies 50A are subsequently bonded to the second integrated circuit die 50B.

In FIG. 33, a second integrated circuit die 50B is attached to a carrier substrate 112 in a face-up manner, such that the back-side of second integrated circuit die 50B is attached to the carrier substrate 112. The second integrated circuit die 50B may be attached to the carrier substrate 112 similar to how the first integrated circuit dies 50A were attached to the carrier substrate 102, as previously described for FIG. 2. A gap-fill dielectric 110 is then formed around the second integrated circuit die 50B, in a similar manner as previously described for FIG. 9.

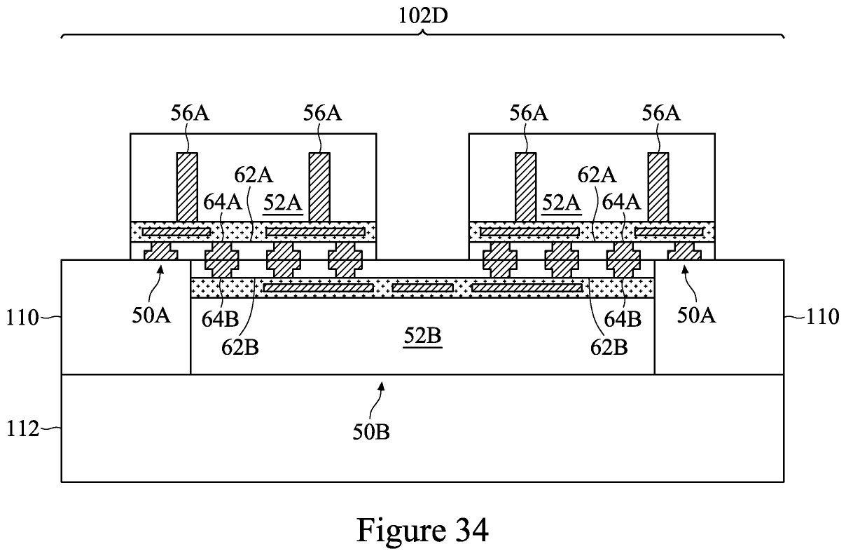

In FIG. 34, first integrated circuit dies 50A are attached to the second integrated circuit die 50B, such that the front-side of the second integrated circuit die 50B faces the front-sides of the first integrated circuit dies 50A. The first integrated circuit dies 50A may be attached to the second integrated circuit die 50B similar to how the second integrated circuit die 50B was attached to the first integrated circuit dies 50A, as previously described for FIG. 8.

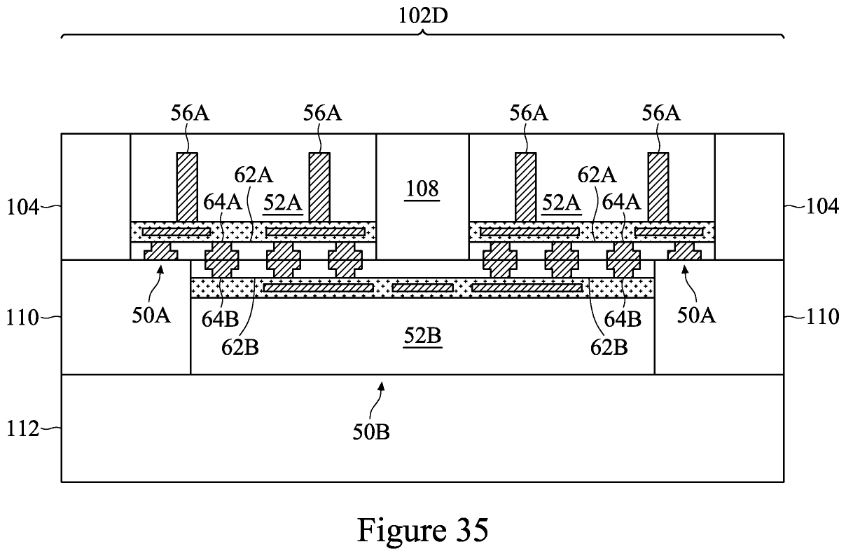

In FIG. 35, an inner gap-fill dielectric 108 and an outer gap-fill dielectric 104 are formed around the first integrated circuit dies 50A. The inner gap-fill dielectric 108 and the outer gap-fill dielectric 104 may be formed using any suitable one of the aforementioned techniques. In this embodiment, the inner gap-fill dielectric 108 may include any of the material stacks previously described for FIG. 13A-13C or 27A-27D, except the layers of the material stacks may be inverted, on account of the layers of the die structure 100 being formed in reverse order.

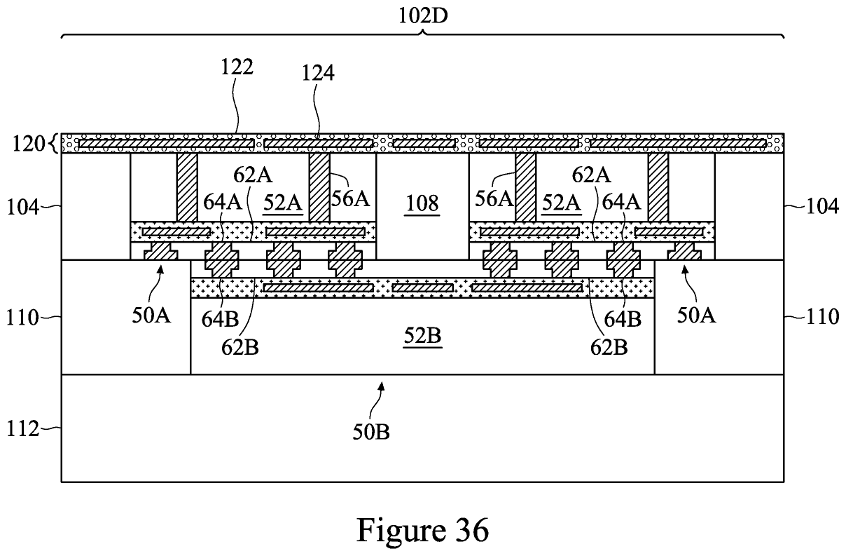

In FIG. 36, the semiconductor substrates 52A of the first integrated circuit dies 50A are thinned to expose the conductive vias 56A of the first integrated circuit dies 50A. The semiconductor substrates 52A may be thinned in a similar manner as previously described for FIG. 10. A redistribution structure 120 is then formed on the back-sides of the first integrated circuit dies 50A, the outer gap-fill dielectric 104, and the inner gap-fill dielectric 108. The redistribution structure 120 may be formed in a similar manner as previously described for FIG. 11. Optionally, the carrier substrate 112 may be removed, or may remain to provide structural support in the completed device. Subsequently, appropriate steps as previously described may be performed to complete the manufacturing of a die structure 100 (see FIG. 12).

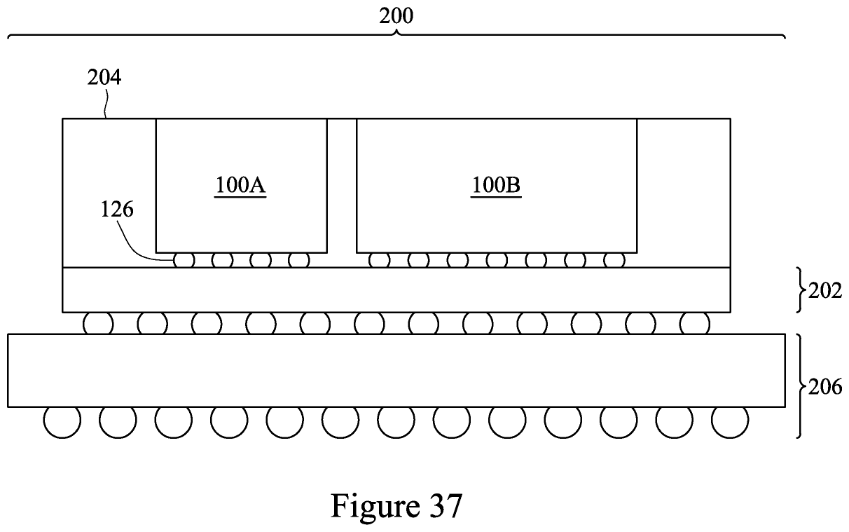

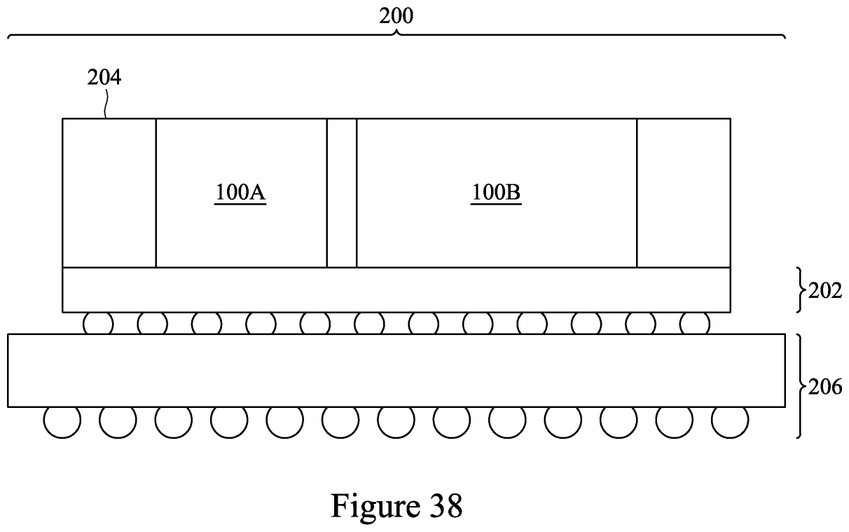

The previously described die structures 100 are components that may be subsequently implemented in an integrated circuit package. The integrated circuit dies 50 of a die structure 100 may be heterogeneous dies. Packaging the die structure 100 in lieu of or in addition to packaging integrated circuit dies individually may allow heterogeneous dies to be integrated with a small footprint. In some embodiments (as subsequently described for FIG. 37), an integrated circuit package is formed by attaching a die structure 100 to an additional component, such as an interposer, a package substrate, or the like. In some embodiments (as subsequently described for FIG. 38), an integrated circuit package is formed by encapsulating the die structure 100 and forming redistribution lines on the encapsulant to fan-out connections from the die structure 100.

FIG. 37 is a cross-sectional view of an integrated circuit package 200, in accordance with some embodiments. The integrated circuit package 200 includes die structures 100 (including a first die structure 100A and a second die structure 100B) attached to a routing structure 202. In this integrated circuit package 200, the die structures 100 include the conductive connectors 126. The first die structure 100A may be different than the second die structure 100B. For example, the first die structure 100A may be a memory device while the second die structure 100B may be a logic device. The routing structure 202 may be an interposer, a redistribution structure, or the like. In the illustrated embodiment, the die structures 100 are attached to the routing structure 202 with the conductive connectors 126. The conductive connectors 126 may be reflowed to attach UBMs of the die structures 100 to die connectors of the routing structure 202. An underfill (not separately illustrated) may be formed around the conductive connectors 126, and between the routing structure 202 and the die structures 100. After the die structures 100 are attached to the routing structure 202, an encapsulant 204 is formed on and around the various components. The encapsulant 204 encapsulates the die structures 100. Subsequently, the routing structure 202 may be attached to a package substrate 206.

FIG. 38 is a cross-sectional view of an integrated circuit package 200, in accordance with some embodiments. The integrated circuit package 200 includes die structures 100 (including a first die structure 100A and a second die structure 100B) encapsulated in an encapsulant 204. In this integrated circuit package 200, the conductive connectors 126 are omitted from the die structures 100. The first die structure 100A may be different than the second die structure 100B. For example, the first die structure 100A may be a memory device while the second die structure 100B may be a logic device. After the die structures 100 are encapsulated in the encapsulant 204, a routing structure 202 is formed on the die structures 100 and/or the encapsulant 204. The routing structure 202 may be a redistribution structure that includes redistribution lines, built up on the die structures 100 and/or the encapsulant 204. The redistribution lines of the routing structure 202 are connected to the die structures 100 and fan-out electrical connections from the die structures 100. Subsequently, the routing structure 202 may be attached to a package substrate 206.

Embodiments may achieve advantages. Forming the inner gap-fill dielectric 108 between the first integrated circuit dies 50A may mitigate the effects of a CTE mismatch between the first integrated circuit dies 50A and the outer gap-fill dielectric 104. Specifically, replacing some of the outer gap-fill dielectric 104 (having a low CTE) with the inner gap-fill dielectric 108 (having a high CTE) can reduce a CTE mismatch in the die structure 100. The risk of warping the die structure 100 and/or inducing undesirable stresses on the integrated circuit dies 50 may be reduced, which may increase the reliability and/or yield of the die structure 100.

In an embodiment, a device includes: an outer gap-fill dielectric having a first coefficient of thermal expansion; a first integrated circuit die in the outer gap-fill dielectric; a second integrated circuit die in the outer gap-fill dielectric; an inner gap-fill dielectric between the first integrated circuit die and the second integrated circuit die, the inner gap-fill dielectric having a second coefficient of thermal expansion, the second coefficient of thermal expansion being greater than the first coefficient of thermal expansion; and a third integrated circuit die over the inner gap-fill dielectric, the third integrated circuit die bonded to the first integrated circuit die and to the second integrated circuit die. In some embodiments of the device, the outer gap-fill dielectric has a first relative permittivity, the inner gap-fill dielectric has a second relative permittivity, and the first relative permittivity is less than the second relative permittivity. In some embodiments of the device, an oxygen concentration of the outer gap-fill dielectric is greater than an oxygen concentration of the inner gap-fill dielectric. In some embodiments of the device, a nitrogen concentration of the inner gap-fill dielectric is greater than a nitrogen concentration of the outer gap-fill dielectric. In some embodiments of the device, a transition metal concentration of the inner gap-fill dielectric is greater than a transition metal concentration of the outer gap-fill dielectric. In some embodiments of the device, the inner gap-fill dielectric is a single, continuous layer of a gap-fill dielectric material. In some embodiments of the device, the inner gap-fill dielectric includes multiple layers of different gap-fill dielectric materials.

In an embodiment, a device includes: an outer gap-fill dielectric; first integrated circuit dies in the outer gap-fill dielectric; an inner gap-fill dielectric between the first integrated circuit dies, the inner gap-fill dielectric including a silicon-based dielectric material that is doped with a non-silicon impurity, the inner gap-fill dielectric having a greater concentration of the non-silicon impurity than the outer gap-fill dielectric; and a second integrated circuit die on the inner gap-fill dielectric and the first integrated circuit dies. In some embodiments of the device, the non-silicon impurity is nitrogen. In some embodiments of the device, the inner gap-fill dielectric is disposed in portions of areas between the first integrated circuit dies that are beneath the second integrated circuit die. In some embodiments of the device, the inner gap-fill dielectric is disposed in all areas between the first integrated circuit dies. In some embodiments of the device, the inner gap-fill dielectric is disposed around the first integrated circuit dies. In some embodiments, the device further includes: a redistribution structure on the first integrated circuit dies, the outer gap-fill dielectric, and the inner gap-fill dielectric. In some embodiments of the device, the inner gap-fill dielectric has a width between the first integrated circuit dies, the inner gap-fill dielectric has a height between the redistribution structure and the second integrated circuit die, and the height is greater than the width.

In an embodiment, a method includes: placing a first integrated circuit die and a second integrated circuit die over a carrier substrate; forming an outer gap-fill dielectric around the first integrated circuit die and the second integrated circuit die, the outer gap-fill dielectric having a first coefficient of thermal expansion; forming an inner gap-fill dielectric between the first integrated circuit die and the second integrated circuit die, the inner gap-fill dielectric having a second coefficient of thermal expansion, the second coefficient of thermal expansion being greater than the first coefficient of thermal expansion; and bonding a third integrated circuit die to the first integrated circuit die and the second integrated circuit die, the third integrated circuit die disposed over the inner gap-fill dielectric. In some embodiments, the method further includes: patterning the outer gap-fill dielectric to form a recess, the inner gap-fill dielectric being formed in the recess. In some embodiments, the method further includes: patterning the inner gap-fill dielectric to form a recess, the outer gap-fill dielectric being formed in the recess. In some embodiments of the method, the inner gap-fill dielectric is formed after the first integrated circuit die and the second integrated circuit die are placed over the carrier substrate. In some embodiments of the method, the inner gap-fill dielectric is formed before the first integrated circuit die and the second integrated circuit die are placed over the carrier substrate. In some embodiments, the method further includes: forming a first spacer and a second spacer, the first spacer disposed between the inner gap-fill dielectric and the first integrated circuit die, the second spacer disposed between the inner gap-fill dielectric and the second integrated circuit die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
an outer gap-fill dielectric having a first coefficient of thermal expansion;
a first integrated circuit die in the outer gap-fill dielectric;
a second integrated circuit die in the outer gap-fill dielectric;
an inner gap-fill dielectric between the first integrated circuit die and the second integrated circuit die, the inner gap-fill dielectric having a second coefficient of thermal expansion, the second coefficient of thermal expansion being greater than the first coefficient of thermal expansion; and
a third integrated circuit die over the inner gap-fill dielectric, the third integrated circuit die bonded to the first integrated circuit die and to the second integrated circuit die.

2. The device of claim 1, wherein the outer gap-fill dielectric has a first relative permittivity, the inner gap-fill dielectric has a second relative permittivity, and the first relative permittivity is less than the second relative permittivity.

3. The device of claim 1, wherein an oxygen concentration of the outer gap-fill dielectric is greater than an oxygen concentration of the inner gap-fill dielectric.

4. The device of claim 1, wherein a nitrogen concentration of the inner gap-fill dielectric is greater than a nitrogen concentration of the outer gap-fill dielectric.

5. The device of claim 1, wherein a transition metal concentration of the inner gap-fill dielectric is greater than a transition metal concentration of the outer gap-fill dielectric.

6. The device of claim 1, wherein the inner gap-fill dielectric is a single, continuous layer of a gap-fill dielectric material.

7. The device of claim 1, wherein the inner gap-fill dielectric comprises multiple layers of different gap-fill dielectric materials.

8. A device comprising:
an outer gap-fill dielectric;
first integrated circuit dies in the outer gap-fill dielectric;
an inner gap-fill dielectric between the first integrated circuit dies, the inner gap-fill dielectric comprising a silicon-based dielectric material that is doped with a non-silicon impurity, the inner gap-fill dielectric having a greater concentration of the non-silicon impurity than the outer gap-fill dielectric; and
a second integrated circuit die on the inner gap-fill dielectric and the first integrated circuit dies.

9. The device of claim 8, wherein the non-silicon impurity is nitrogen.

10. The device of claim 8, wherein the inner gap-fill dielectric is disposed in portions of areas between the first integrated circuit dies that are beneath the second integrated circuit die.

11. The device of claim 8, wherein the inner gap-fill dielectric is disposed in all areas between the first integrated circuit dies.

12. The device of claim 8, wherein the inner gap-fill dielectric is disposed around the first integrated circuit dies.

13. The device of claim 8, further comprising:
a redistribution structure on the first integrated circuit dies, the outer gap-fill dielectric, and the inner gap-fill dielectric.

14. The device of claim 13, wherein the inner gap-fill dielectric has a width between the first integrated circuit dies, the inner gap-fill dielectric has a height between the redistribution structure and the second integrated circuit die, and the height is greater than the width.

15. A method comprising:
placing a first integrated circuit die and a second integrated circuit die over a carrier substrate;
forming an outer gap-fill dielectric around the first integrated circuit die and the second integrated circuit die, the outer gap-fill dielectric having a first coefficient of thermal expansion;
forming an inner gap-fill dielectric between the first integrated circuit die and the second integrated circuit die, the inner gap-fill dielectric having a second coefficient of thermal expansion, the second coefficient of thermal expansion being greater than the first coefficient of thermal expansion; and
bonding a third integrated circuit die to the first integrated circuit die and the second integrated circuit die, the third integrated circuit die disposed over the inner gap-fill dielectric.

16. The method of claim 15, further comprising:
patterning the outer gap-fill dielectric to form a recess, the inner gap-fill dielectric being formed in the recess.

17. The method of claim 15, further comprising:
patterning the inner gap-fill dielectric to form a recess, the outer gap-fill dielectric being formed in the recess.

18. The method of claim 15, wherein the inner gap-fill dielectric is formed after the first integrated circuit die and the second integrated circuit die are placed over the carrier substrate.

19. The method of claim 15, wherein the inner gap-fill dielectric is formed before the first integrated circuit die and the second integrated circuit die are placed over the carrier substrate.

20. The method of claim 19, further comprising:
forming a first spacer and a second spacer, the first spacer disposed between the inner gap-fill dielectric and the first integrated circuit die, the second spacer disposed between the inner gap-fill dielectric and the second integrated circuit die.
